(19) United States
(12) Patent Application Publication
(10) Pub. No.: US 2016/0011779 A1
(43) Pub. Date: Jan. 14, 2016

(54) NONVOLATILE MEMORY DEVICE, MEMORY CONTROLLER, AND OPERATING METHOD OF THE SAME

(71) Applicant: Ji-Sang LEE, Iksan-Si (KR)

(72) Inventor: Ji-Sang LEE, Iksan-Si (KR)

(21) Appl. No.: 14/743,267

(22) Filed: Jun. 18, 2015

(30) Foreign Application Priority Data
Jul. 10, 2014 (KR) 10-2014-0086904

(51) Int. Cl. G06F 3/06; G11C 7/10

(52) U.S. Cl. CPC G06F 3/061; G06F 3/0688; G06F 3/0659; G11C 7/106; G11C 7/1087

(57) ABSTRACT

An operating method of a nonvolatile memory device is provided which includes receiving a command and an address for a program operation of a first plane, and first data to be programmed at the first plane. A multi-plane dumping command is received after the first data is received, and a command and an address for a program operation of a second plane are received. Second data to be programmed at the second plane is received while a multi-plane dumping operation of the first data is conducted on the first plane.

### CROSS-REFERENCE TO RELATED APPLICATIONS

A claim for priority under 35 U.S.C. §119 is made to Korean Patent Application No. 10-2014-0086904 filed Jul. 10, 2014, in the Korean Intellectual Property Office, the entire contents of which are hereby incorporated by reference.

### FIELD

The inventive concepts described herein relate to a nonvolatile memory device and a memory controller, and more particularly, relate to a nonvolatile memory device, a memory controller, and operating methods thereof.

### BACKGROUND

Semiconductor memory devices are divided into volatile memory devices and nonvolatile memory devices. Read and write speeds of the volatile memory device are fast, while they lose contents stored therein at power-off. In contrast, the nonvolatile memory devices retain contents stored therein even at power-off. Thus, the nonvolatile memory devices are used to store contents which must be retained regardless of whether power is supplied. In particular, among nonvolatile memory devices, a flash memory device is advantageous to an appliance as an auxiliary mass storage device in that it is highly integrated as compared with a conventional EEPROM.

For the past several years, a variety of memory systems have been produced with use of the flash memory. The memory system stores or reads data at or from the flash memory through a protocol. A variety of techniques have been proposed to shorten a time taken to conduct the write or read operation of the memory system.

### SUMMARY

One aspect of embodiments of the inventive concept is directed to providing an operating method of a nonvolatile memory device comprising: receiving a command and an address for a program operation of a first plane, and first data to be programmed at the first plane; receiving a multi-plane dumping command after first data is received; and receiving a command and an address for a program operation of a second plane, and second data to be programmed at the second plane while a multi-plane dumping operation on the first plane is conducted or performed.

In exemplary embodiments, a selected physical page of each of the first and second planes is programmed by a one-shot program process.

In exemplary embodiments, the multi-plane dumping operation is conducted between cache latches and data latches of a page buffer circuit corresponding to the first plane.

In exemplary embodiments, the first and second planes share a global buffer included in an input/output circuit.

Another aspect of embodiments of the inventive concept is directed to providing an operating method of a nonvolatile memory device which includes a first plane and a second plane, the operating method comprising: receiving a first program start command and a first address; receiving first page data to be programmed at the first plane based upon the first address; receiving a first multi-plane dumping command after an input of the first page data is completed; receiving a second program start command and a second address while a dumping operation on the first page data is carried out or performed based upon the first multi-plane dumping command; and receiving second page data to be programmed at the second plane depending on the second address.

In exemplary embodiments, the operating method further comprises receiving a second multi-plane dumping command after an input of the second page data is completed; receiving a third program start command and a third address while a dumping operation on the second page data is carried out based upon the second multi-plane dumping command; receiving third page data to be programmed at the first plane depending on the third address; receiving a third multi-plane dumping command after an input of the third page data is completed; receiving a fourth program start command and a fourth address while a dumping operation on the third page data is carried based upon the third multi-plane dumping command; receiving fourth page data to be programmed at the second plane depending on the fourth address; and receiving a fourth multi-plane dumping command after an input of the fourth page data is completed.

In exemplary embodiments, the operating method further comprises conducting a dumping operation on the fourth page data based upon the fourth multi-plane dumping command; receiving a first program execution command and a fifth address corresponding to the first plane after the dumping operation on the fourth page data is completed; and receiving a second program execution command and a sixth address corresponding to the second plane.

In exemplary embodiments, the operating method further comprises receiving a fifth program start command and a fifth address while a dumping operation on the fourth page data is carried out based upon the fourth multi-plane dumping command; receiving fifth page data to be programmed at the first plane depending on the fifth address; receiving a fifth multi-plane dumping command after an input of the fifth page data is completed; receiving a sixth program start command and a sixth address while a dumping operation on the fifth page data is carried out based upon the fifth multi-plane dumping command; receiving sixth page data to be programmed at the second plane depending on the sixth address; and receiving a sixth multi-plane dumping command after an input of the sixth page data is completed.

In exemplary embodiments, the operating method further comprises receiving a first program execution command and a seventh address corresponding to the first plane after a dumping operation on the sixth page data is carried out based upon the sixth multi-plane dumping command; and receiving a second program execution command and an eighth address corresponding to the second plane.

In exemplary embodiments, the dumping operations on the first, third, and fifth page data are conducted between cache latches and data latches of a page buffer circuit corresponding to the first plane, and wherein the dumping operations on the second, fourth, and sixth page data are conducted between cache latches and data latches of a page buffer circuit corresponding to the second plane.

Still another aspect of embodiments of the inventive concept is directed to providing an operating method of a nonvolatile memory device which includes a first plane and a second plane, the operating method comprising: receiving a read start command, an address, and a data sensing command corresponding to each of the first and second planes; outputting first page data sensed from the first plane in response to a first data output command after sensing operations on the first and second planes are conducted based upon the data sensing commands; receiving a first multi-plane dumping command after an output of the first page data is output; and outputting second page data sensed from the second plane in response to a second data output command while a dumping operation on third page data sensed from the first plane is conducted based upon the first multi-plane dumping command.

In exemplary embodiments, the receiving a read start command, an address, and a data sensing command corresponding to each of the first and second planes comprises receiving a first read start command and a first address corresponding to the first plane; receiving a second read start command and a second address corresponding to the second plane; and receiving the data sensing commands corresponding to the first and second addresses.

In exemplary embodiments, the operating method further comprises receiving a second multi-plane dumping command after an output of the second page data is completed; outputting the third page data in response to a third data output command while a dumping operation on fourth page data sensed from the second plane is conducted based upon the second multi-plane dumping command; and outputting the fourth page data in response to a fourth data output command after an output of the third page data is completed.

In exemplary embodiments, the outputting the fourth page data in response to a fourth data output command after an output of the third page data is completed comprises receiving a third multi-plane dumping command after an output of the third page data is completed; outputting the fourth page data in response to the fourth data output command while a dumping operation on fifth page data sensed from the first plane is conducted based upon the third multi-plane dumping command; receiving a fourth multi-plane dumping command after an output of the fourth page data is completed; outputting the fifth page data in response to a fifth data output command while a dumping operation on sixth page data sensed from the second plane is conducted based upon the fourth multi-plane dumping command; and outputting the sixth page data in response to a sixth data output command after an output of the fifth page data is completed.

In exemplary embodiments, each of first through fourth latch direction commands is received just following each of the first through fourth multi-plane dumping commands.

In exemplary embodiments, the dumping operations on the third and fifth page data are conducted between cache latches and data latches of a page buffer circuit corresponding to the first plane.

In exemplary embodiments, the dumping operations on the fourth and sixth page data are conducted between cache latches and data latches of a page buffer circuit corresponding to the second plane.

In exemplary embodiments, in the receiving of the data sensing commands corresponding to the first and second addresses, the first page data is dumped from data latches of a page buffer circuit corresponding to the first plane to cache latches thereof just after a sensing operation on the first plane is completed.

In exemplary embodiments, in the receiving of the data sensing commands corresponding to the first and second addresses, the second page data is dumped from data latches of a page buffer circuit corresponding to the second plane to cache latches thereof just after a sensing operation on the second plane is completed.

In exemplary embodiments, the first and second planes share a global buffer included in an input/output circuit.

A further aspect of embodiments of the inventive concept is directed to providing an operating method of a memory controller which controls a nonvolatile memory device having at least two planes, the operating method comprising: outputting a first program start command and a first address in response to a request of a host; transmitting first page data to a page buffer circuit corresponding to a first plane of the at least two planes, based on the first address; outputting a first multi-plane dumping command after a transfer of the first page data is completed; outputting a second program start command and a second address after the first multi-plane dumping command is output; and transmitting second page data to a page buffer circuit corresponding to a second plane of the at least two planes, based on the second address.

In exemplary embodiments, the operating method further comprises outputting a second multi-plane dumping command after a transfer of the second page data is completed; outputting a third program start command and a third address after the second multi-plane dumping command is output; transmitting third page data to a page buffer circuit corresponding to the first plane, based on the third address; outputting a third multi-plane dumping command after a transfer of the third page data is completed; outputting a fourth program start command and a fourth address after the third multi-plane dumping command is output; and transmitting fourth page data to a page buffer circuit corresponding to the second plane, based on the fourth address.

In exemplary embodiments, the operating method further comprises outputting a fourth multi-plane dumping command after a transfer of the fourth page data is completed; outputting a first program execution command and a fifth address corresponding to the first plane after the fourth multi-plane dumping command is output; and outputting a second program execution command and a sixth address corresponding to the second plane.

In exemplary embodiments, the operating method further comprises outputting a fourth multi-plane dumping command after a transfer of the fourth page data is completed; outputting a fifth program start command and a fifth address after the fourth multi-plane dumping command is output; transmitting fifth page data to a page buffer circuit corresponding to the first plane, based on the fifth address; outputting a fifth multi-plane dumping command after a transfer of the fifth page data is completed; outputting a sixth program start command and a sixth address after the fifth multi-plane dumping command is output; transmitting sixth page data to a page buffer circuit corresponding to the second plane, based on the sixth address; and outputting a sixth multi-plane dumping command after a transfer of the sixth page data is completed.

In exemplary embodiments, the operating method further comprises outputting a first program execution command and a seventh address corresponding to the first plane after the sixth multi-plane dumping command is output; and outputting a second program execution command and an eighth address corresponding to the second plane.

In exemplary embodiments, the first program execution command is output after the sixth multi-plane dumping command is output and a dummy busy time for data set-up elapses.

In exemplary embodiments, first through sixth latch direction commands are respectively output just following the first through sixth multi-plane dumping commands.

Another aspect of embodiments of the inventive concept is directed to providing an operating method of a memory controller which controls a nonvolatile memory device having at least two planes, the operating method comprising: outputting a read start command, an address, and a data sensing command corresponding to each of the at least two planes in response to a request of a host; receiving first page data output from a first plane of the at least two planes in compliance with a first data output command corresponding to the first plane after the data sensing command is output and a page data sensing time elapses; outputting a first multi-plane dumping command after an input of the first page data is ended; and receiving second page data output from a second plane of the at least two planes in compliance with a second data output command corresponding to the second plane after the first multi-plane dumping command is output.

In exemplary embodiments, the outputting of a read start command, an address, and a data sensing command corresponding to each of the at least two planes in response to a request of a host comprises outputting a first read start command and a first address corresponding to the first plane; outputting a second read start command and a second address corresponding to the second plane; and outputting the data sensing commands corresponding to the first and second addresses.

In exemplary embodiments, the operating method further comprises outputting a second multi-plane dumping command after an input of the second page data is ended; receiving third page data output from the first plane based upon a third data output command after the second multi-plane dumping command is output; and receiving the fourth page data output from the second plane based upon a fourth data output command after an input of the third page data is completed.

In exemplary embodiments, the receiving of the fourth page data output from the second plane in compliance with a fourth data output command after an input of the third page data is completed comprises outputting a third multi-plane dumping command after an input of the third page data is ended; receiving the fourth page data output from the second plane based upon the fourth data output command after the third multi-plane dumping command is output; outputting a fourth multi-plane dumping command after an input of the fourth page data is ended; receiving the fifth page data output from the first plane based upon a fifth data output command after the fourth multi-plane dumping command is output; and receiving the sixth page data output from the second plane based upon a sixth data output command after an input of the fourth page data is ended;

In exemplary embodiments, first through fourth latch direction commands are respectively output immediately following the first through fourth multi-plane dumping commands.

An operating method of a memory system which includes a nonvolatile memory device including at least two planes, and a memory controller outputting a multi-plane program sequence to control the nonvolatile memory device is further provided. The operating method comprises: executing a first input operation corresponding to a first plane of the at least two planes based upon the multi-plane program sequence; and executing a second input operation corresponding to a second plane of the at least two planes while a first dumping operation corresponding to the first plane is conducted based upon the multi-plane program sequence.

In exemplary embodiments, the operating method further comprises: executing a third input operation corresponding to the first plane while a second dumping operation corresponding to the second plane is conducted based upon the multi-plane program sequence; executing a fourth input operation corresponding to the second plane while a third dumping operation corresponding to the first plane is conducted based upon the multi-plane program sequence; performing a fourth dumping operation corresponding to the second plane based upon the multi-plane program sequence; and conducting program operations of the first and second planes based upon the multi-plane program sequence.

In exemplary embodiments, performing the fourth dumping operation corresponding to the second plane based upon the multi-plane program sequence comprises: executing a fifth input operation corresponding to the first plane while a fourth dumping operation corresponding to the second plane is conducted based upon the multi-plane program sequence; and executing a sixth input operation corresponding to the second plane while a fifth dumping operation corresponding to the first plane is conducted based upon the multi-plane program sequence.

An operating method of a memory system which includes a nonvolatile memory device including at least two planes, and a memory controller outputting a multi-plane read sequence to control the nonvolatile memory device is further provided. The operating method comprises: sensing a plurality of page data from a selected physical page of each of the at least two planes based upon the multi-plane read sequence; executing a first output operation corresponding to a first plane of the at least two planes based upon the multi-plane read sequence; and executing a second output operation corresponding to a second plane of the at least two planes while a first dumping operation corresponding to the first plane is conducted based upon the multi-plane read sequence.

In exemplary embodiments, the operating method further comprises: executing a third output operation corresponding to the first plane while a second dumping operation corresponding to the second plane is conducted based upon the multi-plane read sequence; and executing a fourth output operation corresponding to the second plane based upon the multi-plane read sequence.

In exemplary embodiments, executing the fourth output operation corresponding to the second plane based upon the multi-plane read sequence comprises: executing a fourth output operation corresponding to the second plane while a third dumping operation corresponding to the first plane is conducted based upon the multi-plane read sequence; executing a fifth output operation corresponding to the first plane while a fourth dumping operation corresponding to the second plane is conducted based upon the multi-plane read sequence; and executing a sixth output operation corresponding to the second plane based upon the multi-plane read sequence.

A memory system is provided which comprises: a nonvolatile memory device including at least two planes; and a memory controller configured to generate a multi-plane operation sequence and control the nonvolatile memory device such that while a dumping operation corresponding to one of the at least two planes is conducted based upon the multi-plane operation sequence, a data input operation or a data output operation corresponding to the other of the at least two planes is conducted.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a block diagram schematically illustrating a memory system according to an embodiment of the inventive concept;

FIG. 2 is a block diagram schematically illustrating a 2-plane nonvolatile memory device;

FIG. 3 is a diagram schematically illustrating a characteristic of a one-shot program operation of a nonvolatile memory device shown in FIG. 2;

FIG. 4 is a perspective view of a memory block BLK shown in FIG. 2;

FIG. 5 is a perspective view schematically illustrating a memory block according to an embodiment of the inventive concept;

FIG. 6 is a circuit diagram schematically illustrating an equivalent circuit of a memory block shown in FIG. 5, according to an embodiment of the inventive concept;

FIG. 7 is a block diagram schematically illustrating a page buffer circuit shown in FIG. 2;

FIG. 8 is a block diagram schematically illustrating data latches shown in FIG. 7;

FIG. 9 is a diagram showing a multi-plane program sequence output from a memory controller during a program operation, according to an embodiment of the inventive concept;

FIG. 10 is a diagram showing a multi-plane read sequence output from a memory controller during a read operation, according to an embodiment of the inventive concept;

FIG. 11 is a diagram showing sequences of addresses and data output command shown in FIGS. 9 and 10;

FIG. 12 is a diagram showing a data transfer order of a program method according to another embodiment of the inventive concept;

FIG. 13 is a diagram showing a multi-plane program sequence produced to execute a program operation method shown in FIG. 12, according to an embodiment of the inventive concept;

FIG. 14 is a flow chart schematically illustrating an operation of a memory controller in compliance with a multi-plane program sequence shown in FIG. 13;

FIG. 15 is a flow chart schematically illustrating an operation of a nonvolatile memory device in compliance with a multi-plane program sequence shown in FIG. 13;

FIG. 16 is a diagram showing a data transfer order of a read operation method according to another embodiment of the inventive concept;

FIG. 17 is a diagram showing a multi-plane read sequence produced to execute a read operation method shown in FIG. 16, according to an embodiment of the inventive concept;

FIG. 18 is a flow chart schematically illustrating an operation of a memory controller in compliance with a multi-plane read sequence shown in FIG. 17;

FIG. 19 is a flow chart schematically illustrating an operation of a nonvolatile memory device in compliance with a multi-plane read sequence shown in FIG. 17;

FIG. 20 is a block diagram schematically illustrating a solid state drive according to an embodiment of the inventive concept;

FIG. 21 is a block diagram schematically illustrating an eMMC according to an embodiment of the inventive concept;

FIG. 22 is a block diagram schematically illustrating a UFS system according to an embodiment of the inventive concept; and

FIG. 23 is a block diagram schematically illustrating a mobile device according to an embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Below, a memory system will be exemplified as an example of a storage device or an electronic device to describe the aspects and functions of the inventive concept. An embodiment of the inventive concept will be exemplified as data is transferred by the sector. However, the inventive concept is not limited thereto. Any other merits and performance of the inventive concept may be easily understood depending on contents disclosed herein. Also, an embodiment of the inventive concept is exemplified as a NAND flash memory that is used as a storage medium. However, the inventive concept is not limited thereto. For example, the storage medium may be implemented with the following: a NOR flash memory, a phase-change RAM (PRAM), a magnetic RAM (MRAM), a resistive RAM (ReRAM), and a ferroelectric RAM (FRAM). The inventive concept is applicable to a memory system including different types of memory devices.

In an embodiment of the present inventive concept, a three dimensional (3D) memory array is provided. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

In an embodiment of the present inventive concept, the 3D memory array includes vertical NAND strings that are vertically oriented such that at least one memory cell is located over another memory cell. The at least one memory cell may comprise a charge trap layer. Each vertical NAND string may include at least one select transistor located over memory cells, the at least one select transistor having the same structure with the memory cells and being formed monolithically together with the memory cells.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

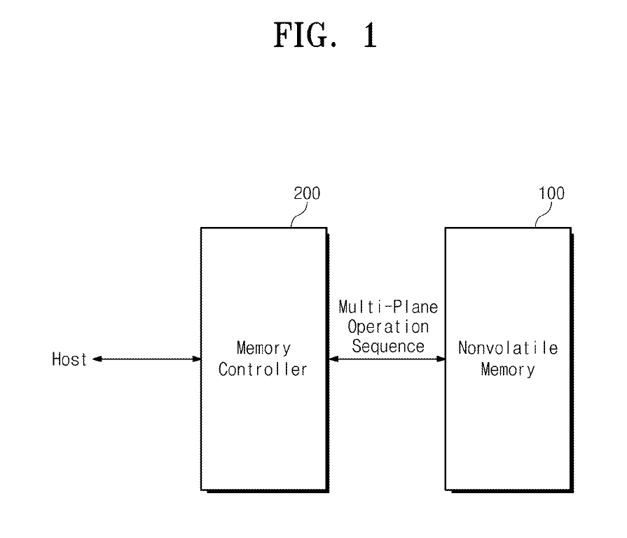

FIG. 1 is a block diagram schematically illustrating a memory system according to an embodiment of the inventive concept. Referring to FIG. 1, a memory system includes a nonvolatile memory device 100 and a controller 200 to control the nonvolatile memory device 100.

The nonvolatile memory device 100 may be, but not limited to, a NAND flash memory device, a vertical NAND flash memory device (or, referred to as VNAND), a NOR flash memory device, a resistive RAM (RRAM) device, a phase-change RAM (PRAM) device, a magneto-resistive RAM (MRAM) device, a ferroelectric RAM (FRAM) device, or a Spin Transfer Torque RAM (STT-RAM). Further, the nonvolatile memory device 100 may be implemented to have a three-dimensional array structure. The inventive concept may be applied to a Charge Trap Flash (CTF) memory device, including a charge storage layer formed of an insulation film and a flash memory device including a charge storage layer formed of a conductive floating gate. For the sake of easy understanding, the nonvolatile memory device 100 will be described as being a NAND flash memory device.

The nonvolatile memory device 100 has a plurality of planes. The term “plane” may mean a memory cell array that is connected to a page buffer circuit operating independently. Data that is received from the memory controller 200 by the page may be stored at each plane. Data that is read out from each plane may be transferred to the memory controller 200 through a corresponding page buffer circuit. Each plane includes a plurality of memory blocks. The nonvolatile memory device 100 conducts read and write operations by the page and an erase operation by the memory block.

The memory controller 200 is connected to the nonvolatile memory device 100. The memory controller 200 is configured to access the nonvolatile memory device 100. For example, the memory controller 200 is configured to control a read operation, a write operation, an erase operation, and a background operation of the nonvolatile memory device 100. The memory controller 200 provides an interface between the nonvolatile memory device 100 and a host. The memory controller 200 is configured to drive firmware for controlling the nonvolatile memory device 100.

The memory controller 200 receives a program or read operation request from the host. The memory controller 200 produces a multi-plane operation sequence in response to the received program or read operation request. The nonvolatile memory device 100 performs a program or read operation in response to the multi-plane operation sequence. For example, the multi-plane operation sequence may include a multi-plane program sequence for a program operation. Also, the multi-plane operation sequence may include a multi-plane read sequence for a read operation.

In exemplary embodiments, the memory controller 200 may include the following: a RAM, a processing unit, a host interface, a memory interface, and an ECC unit. The memory controller 200 may control a program or read operation corresponding to the multi-plane operation sequence to be transmitted through the memory interface.

The memory controller 200 communicates with an external device (e.g., a host) in compliance with a specific communication protocol. For example, the memory controller 200 may communicate with the external device through at least one of a variety of interface protocols, such as, but not limited to, universal serial bus (USB), multimedia card (MMC), peripheral component interconnection (PCI), PCI-express (PCI-E), advanced technology attachment (ATA), serial-ATA, parallel-ATA, small computer small interface (SCSI), enhanced small disk interface (ESDI), integrated drive electronics (IDE), and Firewire.

The memory controller 200 and the nonvolatile memory device 100 may be integrated in a single semiconductor device. For example, the memory controller 200 and the nonvolatile memory device 100 are integrated in a single semiconductor device to form a memory card. For example, the memory controller 200 and the nonvolatile memory device 100 may be integrated in a single semiconductor device to form a memory card, such as, but not limited to, a PC card (PCMCIA, personal computer memory card international association), a compact flash card (CF), a smart media card (SM, SMC), a memory stick, a multimedia card (MMC, RS-MMC, MMCmicro), an SD card (SD, miniSD, microSD, SDHC), or a universal flash storage (UFS).

For example, the memory controller 200 and the nonvolatile memory device 100 may be integrated in a single semiconductor device to form a solid state drive (SSD). The SSD includes a storage device that is configured to store data in a semiconductor memory. When the memory system is used as the SSD, the operating speed of the host connected to the memory system may be markedly increased.

As another example, the memory system may be provided as a computer, a ultra-mobile personal computer (UMPC), a workstation, a net-book, a personal digital assistance (PDA), a portable computer (PC), a web tablet, a wireless phone, a mobile phone, a smart phone, a smart television, a three-dimensional television, an e-book, a portable multimedia player (PMP), a portable game console, a navigation device, a black box, a digital camera, a digital multimedia broadcasting (DMB) player, a digital audio recorder, a digital audio player, a digital picture recorder, a digital picture player, a digital video recorder, a digital video player, a device for transmitting and receiving information in a wireless environment, one of a variety of electronic devices forming a home network, one of a variety of electronic devices forming a computer network, one of a variety of electronic devices forming a telematics network, a radio frequency identification (RFID) device, or one of various components forming a computing system.

The nonvolatile memory device 100 or the memory system according to the inventive concept may be packaged according to any of a variety of different packaging technologies. Examples of such packaging technologies may include the following: PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), and Wafer-Level Processed Stack Package (WSP).

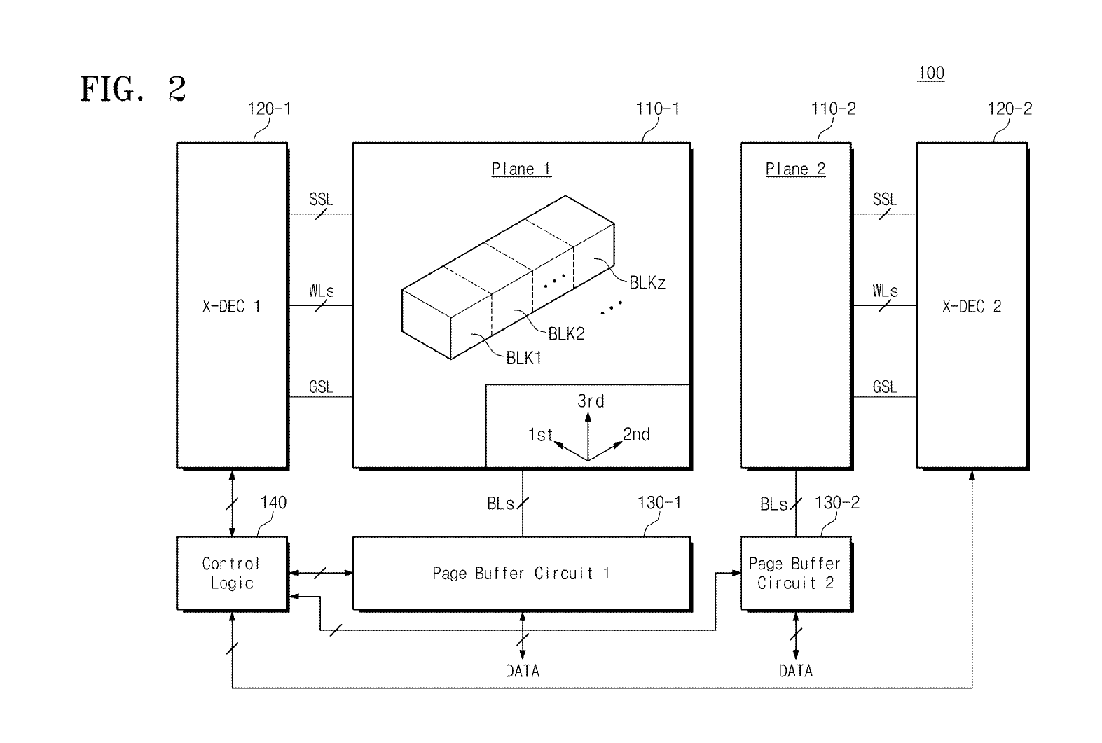

FIG. 2 is a block diagram schematically illustrating a 2-plane nonvolatile memory device 100. Referring to FIG. 2, the nonvolatile memory device 100 includes a first plane 110-1, a second plane 110-2, a first address decoder 120-1, a second address decoder 120-2, a first page buffer circuit 130-1, a second page buffer circuit 130-2, and control logic 140.

Each of the first plane 110-1 and the second plane 110-2 includes a plurality of memory blocks BLK1 to BLKz (z being an integer of 2 or more). Each of the memory blocks BLK1 to BLKz may be connected to the address decoder 120-1 or 120-2 through word lines, at least one string selection line SSL, and at least one ground selection line GSL and to the page buffer circuit 130-1 or 130-2 through bit lines.

The memory blocks BLK1 to BLKz may include a plurality of strings that are three-dimensionally arranged on a substrate along a first direction and a second direction (different from the first direction) and along a third direction (i.e., a direction perpendicular to a plane formed in the first and second directions). Herein, each string may contain at least one string selection transistor, a plurality of memory cells, and at least one ground selection transistor connected in series in a direction perpendicular to the substrate. Each memory cell may store one or more bits. In exemplary embodiments, at least one dummy cell may be provided between at least one string selection transistor and a plurality of memory cells. In other exemplary embodiments, at least one dummy cell may be provided between a plurality of memory cells and at least one ground selection transistor.

Each of the first and second address decoders 120-1 and 120-2 selects one of the memory blocks BLK1 to BLKz in response to an address. Each of the first and second address decoders 120-1 and 120-2 is connected to a memory cell array through the word lines, the at least one string selection line SSL, and the at least one ground selection line GSL. Each of the first and second address decoders 120-1 and 120-2 selects the word lines, the at least one string selection line SSL, and the at least one ground selection line GSL, depending on a decoded row address. Each of the first and second address decoders 120-1 and 120-2 decodes a column address of an input address. Herein, the decoded column address may be transferred to a page buffer circuit 130-1 or 130-2. In exemplary embodiments, each of the first and second address decoders 120-1 and 120-2 may include, but not limited to, a row decoder, a column decoder, an address buffer, and so on.

The first page buffer circuit 130-1 and the second page buffer circuit 130-2 are connected to the first plane 110-1 and the second plane 110-2 through corresponding bit lines. The first and second page buffer circuits 130-1 and 130-2 are configured to receive the decoded column address from the first and second address decoders 120-1 and 120-2. The first and second page buffer circuits 130-1 and 130-2 select the corresponding bit lines depending on the decoded column address.

The first and second page buffer circuits 130-1 and 130-2 receive data from an external device (e.g., a memory controller 200 in FIG. 1) and store the input data in the first and second planes 110-1 and 110-2. The first and second page buffer circuits 130-1 and 130-2 read data from the first and second planes 110-1 and 110-2 and output the read data to the external device.

In exemplary embodiments, each of the first and second page buffer circuits 130-1 and 130-2 may store a plurality of page data in one physical page at the same time. Each of the first and second page buffer circuits 130-1 and 130-2 may include latches (not shown) to store a plurality of page data. A plurality of page data stored in latches of the first page buffer circuit 130-1 may be exchanged with a plurality of page data stored in latches of the second page buffer circuit 130-2, which will be called ‘page data exchanging’. Below, an operation of exchanging page data among latches will be referred to as a dumping operation.

The control logic 140 controls an overall operation of the nonvolatile memory device 100 including, but not limited to, a program operation, a read operation, and an erase operation. The control logic 140 operates in response to control signals and commands that are output from the memory controller 200 in compliance with the multi-plane operation sequence.

For example, the control logic 140 may control one of the address decoders 120-1 and 120-2 and one of the page buffer circuits 130-1 and 130-2 such that a plurality of page data is programmed at one physical page in compliance with the multi-plane operation sequence. Also, the control logic 140 may control one of the address decoders 120-1 and 120-2 and one of the page buffer circuits 130-1 and 130-2 such that a plurality of page data read from one physical page is sequentially output in compliance with the multi-plane operation sequence. The control logic 140 receives a page data exchange command in compliance with the multi-plane operation sequence and controls an operation of exchanging data among latches of the page buffer circuit 130-1 or 130-2 in response to the page data exchange command.

Although not shown in FIG. 2, the nonvolatile memory device 100 may further contain an input/output circuit. The input/output circuit may be connected to the first and second address decoders 120-1 and 120-2, the first and second page buffer circuits 130-1 and 130-2, and the control logic 140. The input/output circuit may include a global buffer that temporarily stores commands, addresses, and data received from the memory controller 200. The first and second page buffer circuits 130-1 and 130-2 may share the global buffer included in the input/output circuit.

As described above, the nonvolatile memory device 100 according to an embodiment of the inventive concept may support a multi-plane operation mode based on the multi-plane operation sequence. The multi-plane operation mode may be applied to both a program operation and a read operation.

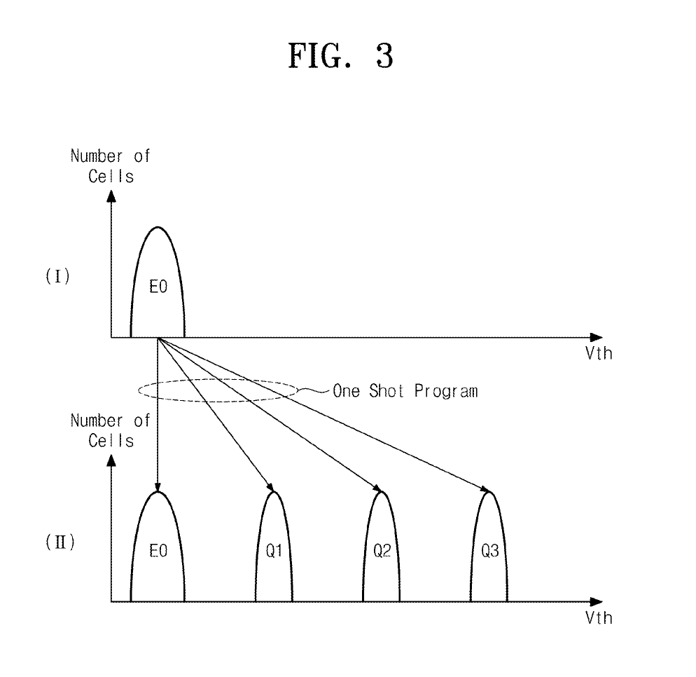

FIG. 3 is a diagram schematically illustrating a characteristic of a one-shot program operation of a nonvolatile memory device shown in FIG. 2. Referring to FIG. 3, a top graph (I) shows a threshold voltage distribution of memory cells before a program operation is executed, and a bottom graph (II) shows threshold voltage distributions of memory cells after a one-shot program operation is executed.

As understood from the top graph (I), before programmed, all memory cells have threshold voltages corresponding to an erase state E0. When erased, selected memory cells have threshold voltages corresponding to the erase state E0. The one-shot program operation is conducted when there is provided data of the maximum capacity that the selected memory cells are able to store.

The one-shot program operation may be a program operation where multi-bit data to be stored at a multi-level cell is stored during one program cycle. For example, in case of a 2-bit multi-level cell, 2-bit data may be stored at a memory cell through the one-shot program operation during one program cycle. The program cycle is formed of a plurality of increasing program pulses and verification pulses corresponding to target states Q1 through Q3 and following the program pulses. That is, the one-shot program operation may be contrasted with a shadow program operation where 1-bit data is stored at a multi-level cell during one program cycle.

An embodiment of the inventive concept is exemplified as memory cells that are 2-bit multi-level cells. However, the inventive concept is not limited thereto. Although not shown in figures, in case of a 3-bit multi-level cell, 3-bit data may be programmed at a memory cell through the one-shot program operation during one program cycle. The program cycle is formed of a plurality of increasing program pulses and verification pulses corresponding to target states Q1 through Q7 and following the program pulses.

The one-shot program operation may be used in a vertical nonvolatile memory device where interference between word lines, such as program disturbance, is not problematic. During a read operation, the nonvolatile memory device may read multi-level data, which has been programmed through the one-shot program operation, by performing only one sensing operation.

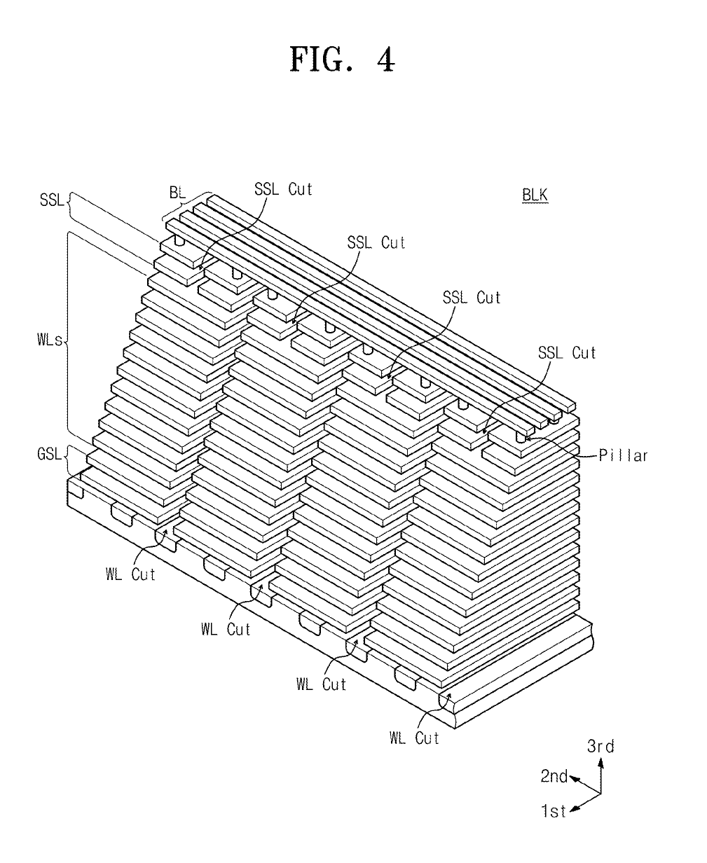

FIG. 4 is a perspective view of a memory block BLK shown in FIG. 2. Referring to FIG. 4, four sub blocks are formed on a substrate. Each sub block is formed by stacking and cutting at least one ground selection line GSL, a plurality of word lines, and at least one string selection line SSL on the substrate in a plate shape. In exemplary embodiments, the at least one string selection line SSL may be separated by string selection line cuts. Herein, the at least one string selection line SSL may be separated by a string selection line cut.

In exemplary embodiments, at least one plate-shaped dummy line may be formed between the ground selection line GSL and the word lines. Alternatively, at least one plate-shaped dummy line may be formed between the word lines and the string selection line SSL.

Although not shown in FIG. 4, each word line cut may include a common source line CSL. For example, the common source lines CSL included in the word line cuts may be interconnected. A string may be formed in such a way that a pillar connected to a bit line penetrates the at least one string selection line SSL, the word lines, and the at least one ground selection line GSL.

In FIG. 4, an embodiment of the inventive concept is exemplified as a structure between word line cuts adjacent to each other is a sub block. However, the inventive concept is not limited thereto. For example, a structure between a word line cut and a string selection line cut may be defined as a sub block.

The memory block BLK according to an embodiment of the inventive concept may be implemented to have a merged word line structure where two word lines are merged to one.

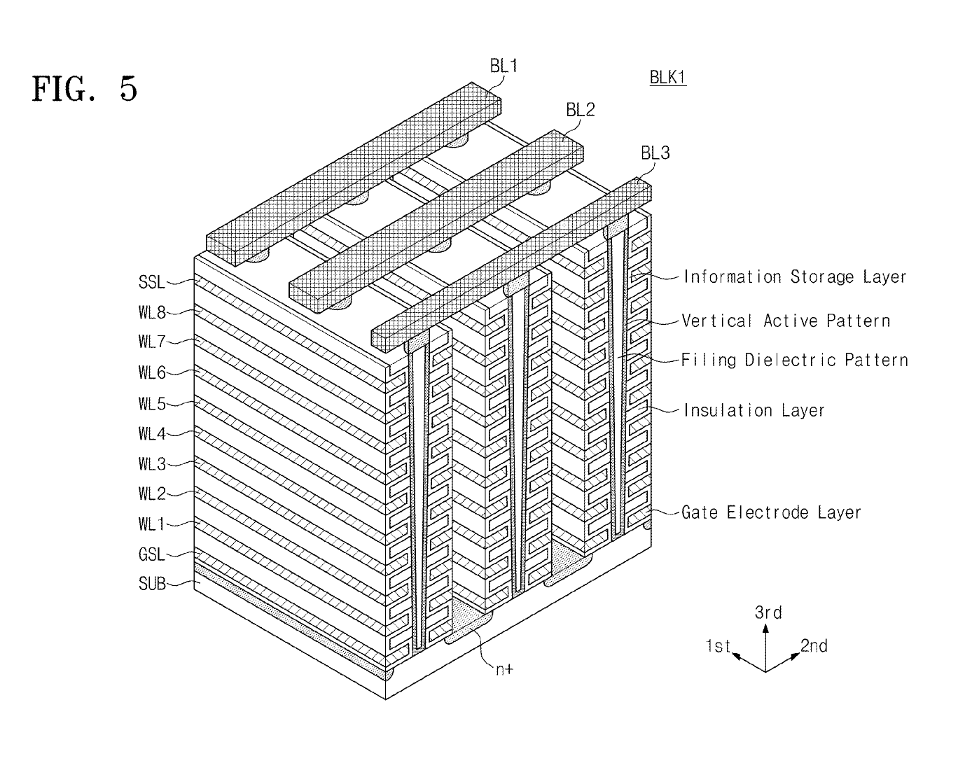

FIG. 5 is a perspective view schematically illustrating a memory block BLK1 according to an embodiment of the inventive concept. Referring to FIG. 5, a memory block BLK1 is formed in a direction perpendicular to a substrate SUB. An n+ doping region is formed in the substrate SUB to extend in a first direction.

A gate electrode layer and an insulation layer are alternately deposited on the substrate SUB. An information storage layer is formed between the gate electrode layer and the insulation layer. If the gate electrode layer and the insulation layer are patterned in a vertical direction, a V-shaped pillar is formed. The pillar is connected to the substrate SUB through the gate electrode layer and the insulation layer. An outer portion of the pillar may be formed of a channel semiconductor as a vertical active pattern, and an inner portion thereof may be formed of an insulation material such as silicon oxide as a filing dielectric pattern.

The gate electrode layer of the memory block BLK1 is connected to a ground selection line GSL, a plurality of word lines WL1 to WL8, and a string selection line SSL. The pillars of the memory block BLK1 are connected to a plurality of bit lines BL1 to BL3. In FIG. 5, an embodiment of the inventive concept is exemplified as one memory block BLK1 that has two selection lines SSL and GSL, eight word lines WL1 to WL8, and three bit lines BL1 to BL3. However, the inventive concept is not limited thereto.

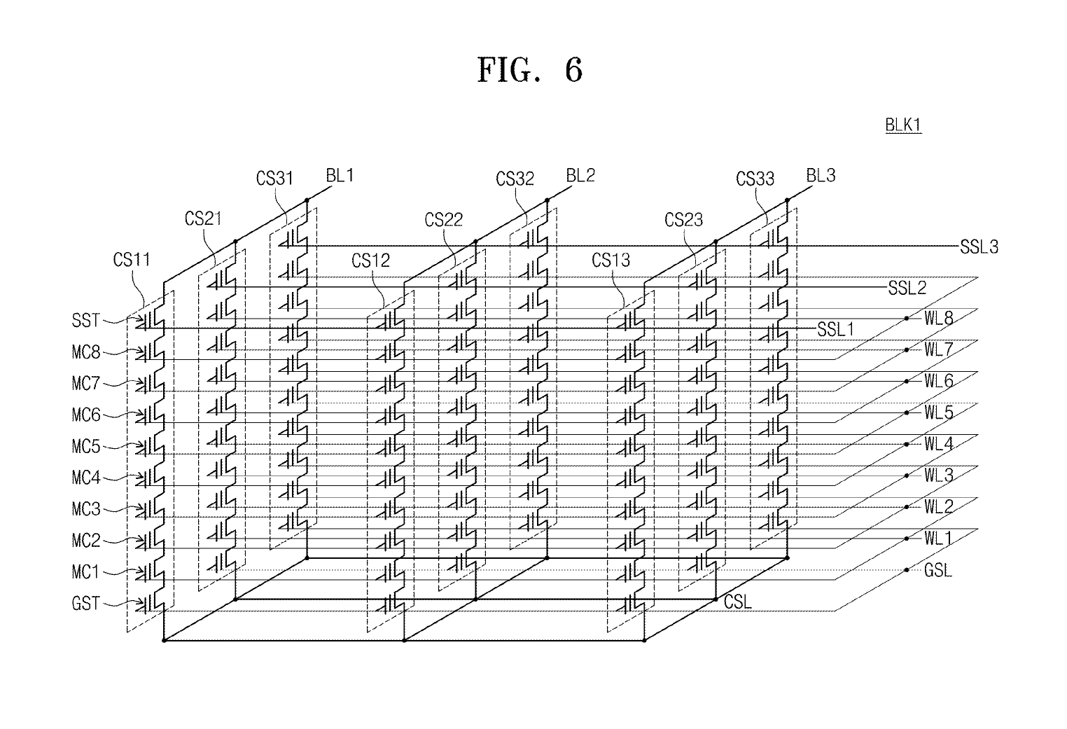

FIG. 6 is a circuit diagram schematically illustrating an equivalent circuit of a memory block BLK1 shown in FIG. 5, according to an embodiment of the inventive concept. Referring to FIG. 6, cell strings CS11 through CS33 are connected between bit lines BL1 through BL3 and a common source line CSL. Each cell string (e.g., CS11) includes a string selection transistor SST, a plurality of memory cells MC1 to MC8, and a ground selection transistor GST.

The string selection transistors SST are connected to a string selection line SSL. The string selection lines SSL are divided into first to third string selection lines SSL1 to SSL3. In FIG. 6, there are illustrated three string selection line SSL1 to SSL3 corresponding to a bit line. However, the inventive concept is not limited thereto. The memory block BLK1 of the inventive concept may be implemented to include at least two string selection lines corresponding to a bit line.

The ground selection transistors GST are connected to a ground selection line GSL. A ground selection line of each cell string may be connected. The string selection transistors SST are connected to bit lines, and the ground selection transistors GST are connected to the common source line CSL. The memory block BLK1 shown in FIG. 4 has a structure in which a ground selection line GSL is shared. However, the inventive concept is not limited thereto. For example, the ground selection line GSL may be implemented such that the ground selection line GSL is divided as the string selection lines SSL1 through SSL3 are divided.

The memory cells MC1 through MC8 are connected to corresponding word lines WL1 through WL8. A set of memory cells that are connected to a word line and are programmed at the same time is referred to as a page. The memory block BLK1 is formed of a plurality of pages. A plurality of pages may be connected to one word line. Referring to FIG. 6, word lines (e.g., WL4) at the same height from the common source line CSL may be connected in common to three pages.

Meanwhile, each memory cell may store 1-bit data or two or more bits of data. A memory cell storing 1-bit data may be referred to as a single-level cell (SLC) or a single-bit cell. A memory cell storing two or more bits of data may be referred to as a multi-level cell (MLC) or a multi-bit cell. In case of a 2-bit MLC, two pages of data are stored at a physical page. This means that six pages of data are stored at memory cells connected to the fourth word line WL4.

Meanwhile, a nonvolatile memory device 100 may be implemented with a charge trap flash (CTF) memory device. In this case, there may be generated the initial verify shift (IVS) phenomenon that charge trapped in programmed CTF is redistributed and leaked by lapse of time. Reprogramming may be performed to overcome such distribution deterioration.

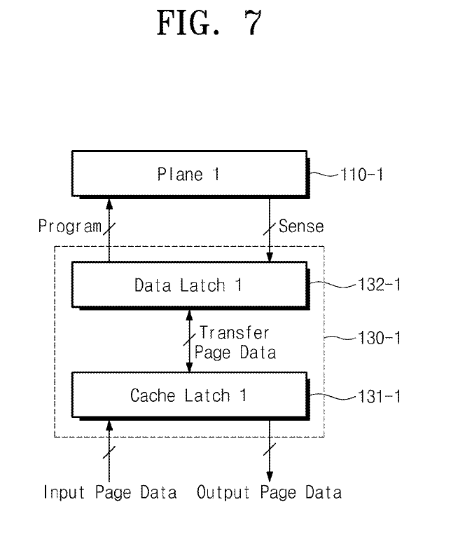

FIG. 7 is a block diagram schematically illustrating a page buffer circuit shown in FIG. 2. Referring to FIG. 7, a page buffer circuit 130-1 contains cache latches 131-1 and data latches 132-1. In FIG. 7, an embodiment of the inventive concept is exemplified as the page buffer circuit 130-1 is connected to a first plane 110-1. All page buffer circuits 130-1 and 130-2 of a nonvolatile memory device 100 may have the same structure as the page buffer circuit 130-1.

The data latches 132-1 store a plurality of page data, and the number of the data latches 132-1 is more than the number of the cache latches 131-1. A nonvolatile memory device 100 according to an embodiment of the inventive concept programs the plurality of page data stored in the data latches 132-1 at a selected physical page of the first plane 110-1 at the same time. The nonvolatile memory device 100 simultaneously senses a plurality of page data programmed at a selected physical page of the first plane 110-1 and stores the sensed page data at the data latches 132-1. A physical page means a set of memory cells that are connected to a word line in any one plane.

During a program operation, the cache latches 131-1 receive a page of data. The cache latches 131-1 transmit the received page data to the data latches 132-1 and then receive another page of data. The data latches 132-1 receive a page of data from the cache latches 131-1 at a time. The data latches 132-1 may store a plurality of page data. The plurality of page data may be simultaneously programmed at a selected physical page of the first plane 110-1 through a one-shot program operation.

During a read operation, a plurality of page data is simultaneously sensed from a selected physical page of the first plane 110-1, and the sensed page data is stored in the data latches 132-1. A plurality of page data is transmitted to the cache latches by the page. After outputting a page of data, the cache latches 131-1 receive another page of data from the data latches 132-1.

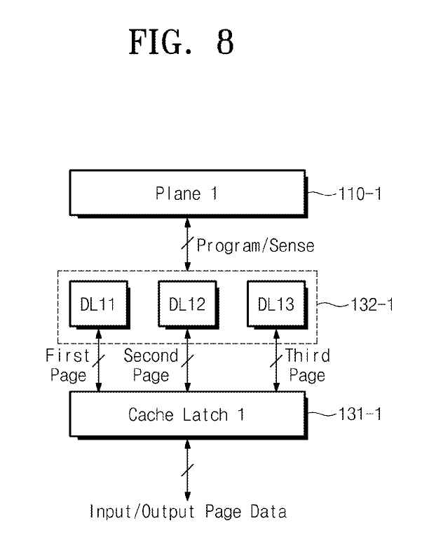

FIG. 8 is a block diagram schematically illustrating data latches shown in FIG. 7. Referring to FIG. 8, data latches 132-1 includes first, second, and third data latches DL11, DL12, and DL13. In FIG. 8, an embodiment of the inventive concept is exemplified as a page buffer circuit 130-1 that is connected to a first plane 110-1. All page buffer circuits 130-1 and 130-2 of a nonvolatile memory device 100 may have the same structure as the page buffer circuit 130-1. Below, it is assumed that each memory cell of the first plane 110-1 is a multi-level cell storing 3-bit data. However, the inventive concept is not limited thereto.

During a program operation, cache latches 131-1 receive first page data. After sending the first page data cache to first data latches DL11, the cache latches 131-1 receive second page data. After sending the second page data cache to second data latches DL12, the cache latches 131-1 receive third page data. The cache latches 131-1 transmit the third page data to third data latches DL13. The first through third page data stored in the first through third data latches DL11 through D113 may be simultaneously programmed at a selected physical page of the first plane 110-1 through one-shot programming.

During a read operation, first through third page data is simultaneously sensed from a selected physical page of the first plane 110-1, and the sensed first through third page data is stored in the first through third data latches DL11 through DL13. For example, the first page data is stored in the first data latches DL11, the second page data in the second data latches DL12, and the third page data in the third data latches DL13. The first through third page data is transmitted to the cache latches 131-1. For example, the first page data is transmitted to the cache latches 131-1 from the first data latches DL11. After the first page data is transmitted, the second page data is sent to the cache latches 131-1 from the second data latches DL12. After the second page data is transmitted, the third page data is provided to the cache latches 131-1 from the third data latches DL13. The read operation may end after the third page data is output.

The first page data, second page data, and third page data of each of planes 110-1 and 110-2 are least significant bit (LSB) page data, central significant bit (CSB) page data, and most significant bit (MSB) page data. For example, the first page data of each of planes 110-1 and 110-2 is the LSB page data, the second page data of each of planes 110-1 and 110-2 is CSB page data, and third page data of each of planes 110-1 and 110-2 is MSB page data.

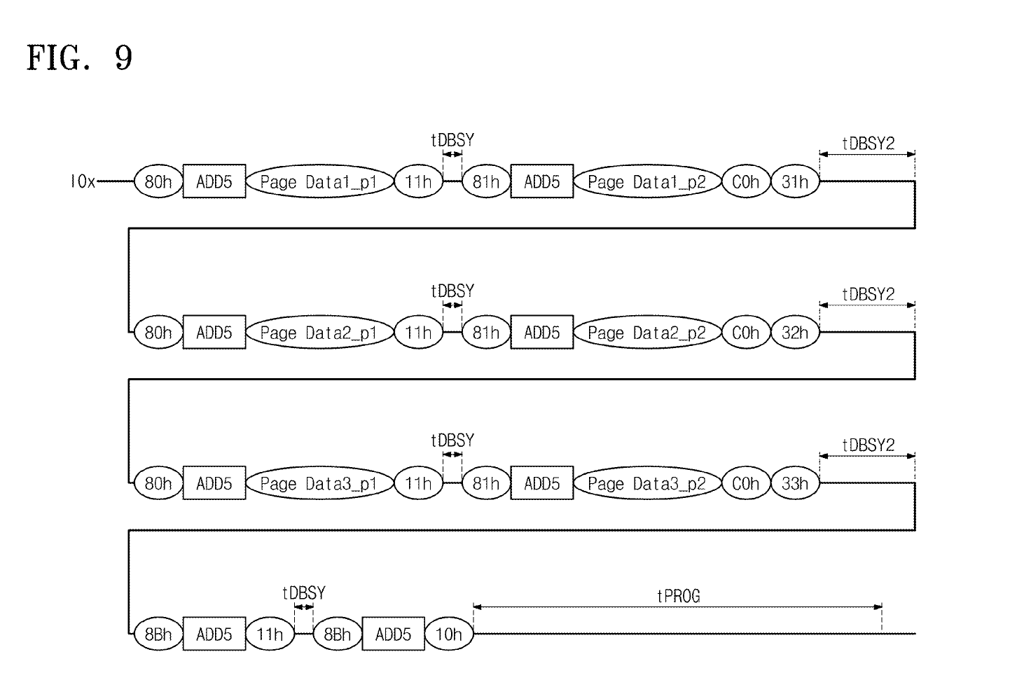

FIG. 9 is a diagram showing a multi-plane program sequence output from a memory controller during a program operation, according to an embodiment of the inventive concept. Referring to FIG. 9, a memory controller 200 (refer to FIG. 1) produces a multi-plane program sequence in response to a program operation request of a host. A nonvolatile memory device 100 performs a program operation in compliance with the multi-plane program sequence. The multi-plane program sequence may be formed of four program sequences as follows.

In a first program sequence, after a program sequence start command 80h and an address ADDS are received, first page data Page Data1_p1 of a first plane is transmitted to a page buffer circuit 130-1 (refer to FIG. 2) of the first plane. The first page data Page Data1_p1 of the first plane is stored in cache latches of the page buffer circuit 130-1 of the first plane. After a confirm command 11h is received and a dummy busy time tDBSY for two-plane programming elapses, a program sequence start command 81h and an address ADDS are received. After the program sequence start command 81h and the address ADDS are received, first page data Page Data1_p2 of a second plane is transmitted to a page buffer circuit 130-2 (refer to FIG. 2) of the second plane. The first page data Page Data1_p2 of the second plane is stored in cache latches of the page buffer circuit 130-2 of the second plane. When a multi-plane dumping command C0h and a latch direction command 31h are received, the first page data Page Data1_p1 and Page Data1_p2 of the first and second planes may be transmitted from the cache latches to first data latches. The dumping operation may be conducted during a dummy busy time tDBSY2 for data set-up.

In a second program sequence, after a program sequence start command 80h and an address ADDS are received, second page data Page Data2_p1 of the first plane is transmitted to the page buffer circuit 130-1 of the first plane. The second page data Page Data2_p1 of the first plane is stored in the cache latches of the page buffer circuit 130-1 of the first plane. After a confirm command 11h is received and a dummy busy time tDBSY for two-plane programming elapses, a program sequence start command 81h and an address ADDS are received. After the program sequence start command 81h and the address ADDS are received, second page data Page Data2_p2 of the second plane is transmitted to the page buffer circuit 130-2 of the second plane. The second page data Page Data2_p2 of the second plane is stored in the cache latches of the page buffer circuit 130-2 of the second plane. When a dumping command C0h and a latch direction command 31h are received, the second page data Page Data2_p1 and Page Data2_p2 of the first and second planes may be transmitted from the cache latches to second data latches. The dumping operation may be conducted during the dummy busy time tDBSY2 for data set-up.

In a third program sequence, after a program sequence start command 80h and an address ADDS are received, third page data Page Data3_p1 of the first plane is transmitted to the page buffer circuit 130-1 of the first plane. The third page data Page Data3_p1 of the first plane is stored in the cache latches of the page buffer circuit 130-1 of the first plane. After a confirm command 11h is received and a dummy busy time tDBSY for two-plane programming elapses, a program sequence start command 81h and an address ADDS are received. After the program sequence start command 81h and the address ADDS are received, third page data Page Data3_p2 of the second plane is transmitted to the page buffer circuit 130-2 of the second plane. The third page data Page Data3_p2 of the second plane is stored in the cache latches of the page buffer circuit 130-2 of the second plane. When a dumping command C0h and a latch direction command 33h are received, the third page data Page Data3_p1 and Page Data3_p2 of the first and second planes may be transmitted from the cache latches to second data latches. The dumping operation may be conducted during the dummy busy time tDBSY2 for data set-up.

In a fourth program sequence, a program start command 8Bh, an address ADDS, and a confirm command 11h corresponding to the first plane are received. After the confirm command 11h is received and a dummy busy time tDBSY for two-plane programming elapses, a program start command 8Bh and an address ADDS corresponding to the second plane are received. After the program execution command 10h is received, program operations of the first and second planes 110-1 and 110-2 are executed. For example, during a program time tPROG, program operations of the first and second planes 110-1 and 110-2 are executed at the same time. Also, the first through third page data Page Data1_p1 through Page Data3_p1 of the first plane are simultaneously programmed at a selected physical page through one-shot programming. The first through third page data Page Data1_p2 through Page Data3_p2 of the second plane are simultaneously programmed at a selected physical page through one-shot programming.

The first page data Page Data1_p1, the second page data Page Data2_p1, and the third page data Page Data3_p1 of the first plane are LSB, CSB, or MSB page data, and the first page data Page Data1_p2, the second page data Page Data2_p2, and the third page data Page Data3_p2 of the second plane are LSB, CSB, or MSB page data. For example, first page data Page Data1_p1 and Page Data1_p2 of the first and second planes are LSB page data, second page data Page Data2_p1 and Page Data2_p2 of the first and second planes are CSB page data, and third page data Page Data3_p1 and Page Data3_p2 of the first and second planes are MSB page data.

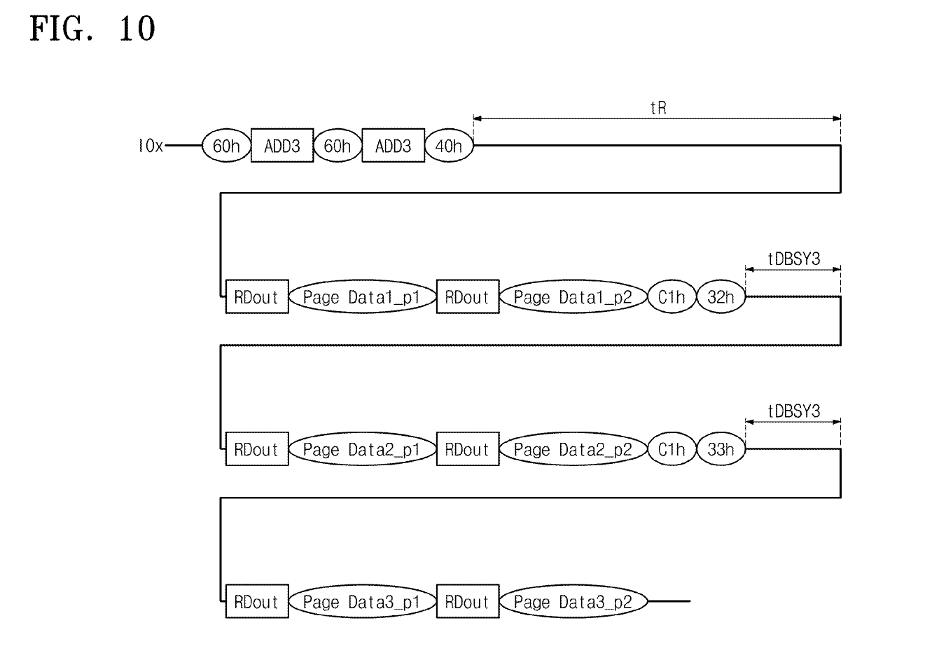

FIG. 10 is a diagram showing a multi-plane read sequence output from a memory controller during a read operation, according to an embodiment of the inventive concept. Referring to FIG. 10, a memory controller 200 (refer to FIG. 1) produces a multi-plane read sequence in response to a read operation request of a host. A nonvolatile memory device 100 performs a read operation in compliance with the multi-plane read sequence. The multi-plane read sequence may be formed of four read sequences as follows.

In a first read sequence, a read start command 60h and an address ADD3 corresponding to a first plane are received, and then a read start command 60h and an address ADD3 corresponding to a second plane are received. After a data sensing command 40h is received, pages data Page Data1_p1, Page Data2_p1, Page Data3_p1, Page Data1_p2, Page Data2_p2, and Page Data3_p2 are simultaneously sensed from selected pages of the first and second planes. The sensed pages data Page Data1_p1, Page Data2_p1, Page Data3_p1, Page Data1_p2, Page Data2_p2, and Page Data3_p2 are stored in data latches of the first and second planes.

The first through third page data Page Data1_p1 through Page Data3_p1 are sensed from the first plane, and the sensed first through third page data Page Data1_p1 through Page Data3_p1 are stored at first through third data latches of the first plane. For example, the first page data Page Data1_p1 is stored in the first data latches, the second page data Page Data2_p1 in the second data latches, and the third page data Page Data3_p1 in the third data latches. During a read time tR, the first through third page data Page Data1_p1 through Page Data3_p1 are sensed from the first plane, and the sensed first through third page data Page Data1_p1 through Page Data3_p1 are stored at the first through third data latches of the first plane. During the read time tR, also, the first page data Page Data1_p1 is transmitted from the first data latches to cache latches.

The first through third page data Page Data1_p2 through Page Data3_p2 are sensed from the second plane, and the sensed first through third page data Page Data1_p2 through Page Data3_p2 are stored at first through third data latches of the second plane. For example, the first page data Page Data1_p2 is stored in the first data latches, the second page data Page Data2_p2 in the second data latches, and the third page data Page Data3_p2 in the third data latches. During a read time tR, the first through third page data Page Data1_p2 through Page Data3_p2 are sensed from the second plane, and the sensed first through third page data Page Data1_p2 through Page Data3_p2 are stored at the first through third data latches of the second plane. During the read time tR, the first page data Page Data1_p2 is transmitted from the first data latches to cache latches.

Thus, during the read time tR, the first through third page data Page Data1_p1 through Page Data3_p1 are sensed from a selected physical page of the first plane, and the first through third page data Page Data1_p2 through Page Data3_p2 are sensed from a selected physical page of the second plane.

In a second read sequence, the first page data Page Data1_p1 of the first plane is output in response to an input of a data output command RDout corresponding to the first plane, and the first page data Page Data1_p2 of the second plane is output in response to a data output command RDout corresponding to the second plane. After a multi-plane dumping command C1h and a latch direction command 32h on the second data latches are received, the second page data Page Data2_p1 and Page Data2_p2 of the first and second planes are simultaneously transmitted from the second data latches to cache latches. For example, the second page data Page Data2_p1 of the first plane is transferred from the second data latches of the first plane to the cache latches thereof during a dummy time tDBSY3 for data-out. The second page data Page Data2_p2 of the second plane is transferred from the second data latches of the second plane to the cache latches thereof during the dummy time tDBSY3 for data-out.

In a third read sequence, the second page data Page Data2_p1 of the first plane is output in response to a data output command RDout corresponding to the first plane, and the second page data Page Data2_p2 of the second plane is output in response to a data output command RDout corresponding to the second plane. After a multi-plane dumping command C1h and a latch direction command 32h on the third data latches are received, the third page data Page Data3_p1 and Page Data3_p2 of the first and second planes are simultaneously transmitted from the third data latches to the cache latches. For example, the third page data Page Data3_p1 of the first plane is transferred from the third data latches of the first plane to the cache latches thereof during a dummy time tDBSY3 for data-out. The third page data Page Data3_p2 of the second plane is transferred from the third data latches of the second plane to the cache latches thereof during the dummy time tDBSY3 for data-out.

In a fourth read sequence, the third page data Page Data3_p1 of the first plane is output in response to a data output command RDout corresponding to the first plane, and the third page data Page Data3_p2 of the second plane is output in response to a data output command RDout corresponding to the second plane.

The first page data Page Data1_p1, the second page data Page Data2_p1, and the third page data Page Data3_p1 of the first plane are LSB, CSB, or MSB page data, and the first page data Page Data1_p2, the second page data Page Data2_p2, and the third page data Page Data3_p2 of the second plane are LSB, CSB, or MSB page data. For example, first page data Page Data1_p1 and Page Data1_p2 of the first and second planes are LSB page data, second page data Page Data2_p1 and Page Data2_p2 of the first and second planes are CSB page data, and third page data Page Data3_p1 and Page Data3_p2 of the first and second planes are MSB page data.

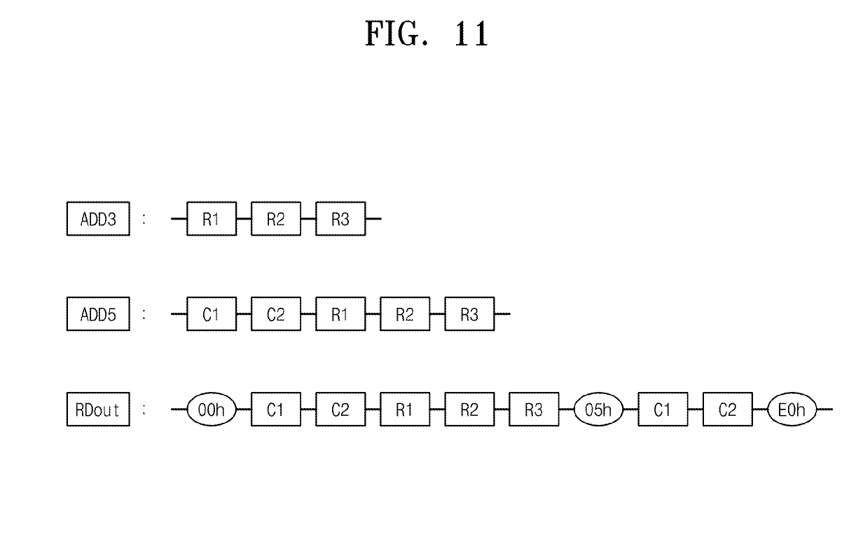

FIG. 11 is a diagram showing sequences of addresses ADDS and ADDS and the data output command RDout shown in FIGS. 9 and 10. Referring to FIG. 11, during a program operation, an address ADDS included in a multi-plane program sequence contains column addresses C1 and C2 and row addresses R1, R2, and R3. During the program operation, a word line may be selected in response to the column addresses C1 and C2 and the row addresses R1, R2, and R3. That is, a selected physical page may be selected in compliance with the address ADDS.

During a read operation, an address ADDS included in a multi-plane read sequence contains row addresses R1, R2, and R3. During the read operation, a word line corresponding to the row addresses RE R2, and R3 may be selected. During the read operation, the data output command RDout included in the multi-plane read sequence includes a data output start command 00h, a column selection command 05h, and a confirm command E0h. After the data output start command 00h is received, column addresses C1 and C2 and row addresses R1, R2, and R3 are received. A word line may be selected in compliance with the column addresses C1 and C2 and the row addresses R1, R2, and R3. After the column selection command 05h is received, column addresses C1 and C2 are received. Page data of a selected plane is output based on the column addresses C1 and C2. The page data of the selected plane is output after the confirm command E0h is received.

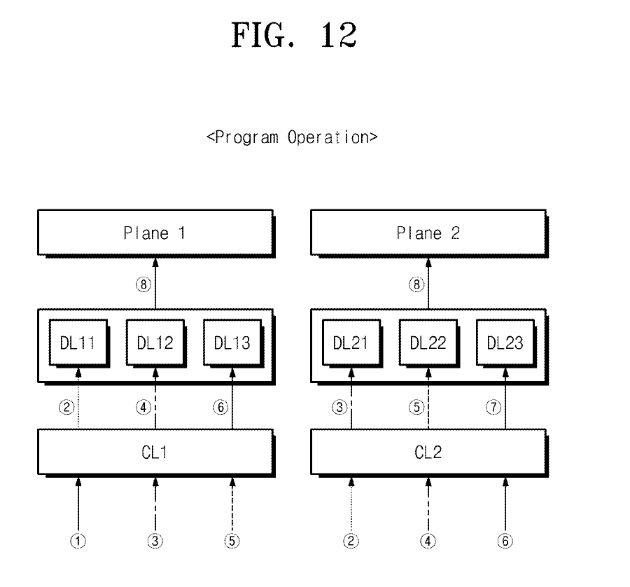

FIG. 12 is a diagram showing a data transfer order of a program method according to another embodiment of the inventive concept. Referring to FIG. 12, it is assumed that a page buffer circuit corresponding to each plane contains cache latches for storing a page of data and data latches for storing three pages of data. For example, a page buffer circuit corresponding to a first plane includes cache latches CL1 and data latches DL11, DL12, and DL13, and a page buffer circuit corresponding to a second plane includes cache latches CL2 and data latches DL21, DL22, and DL23. A nonvolatile memory device 100 (refer to FIG. 1) may perform the following operations (1) through (8) in compliance with a multi-plane program sequence that a memory controller 200 (refer to FIG. 1) generates.

First page data of the first plane is transmitted to the cache latches CL1 of the first plane (1). While first page data of the second plane is transmitted to the cache latches CL2, the first page data of the first plane is sent to the first data latches DL11 of the first plane (2).

While second page data of the first plane is transmitted to the cache latches CL1, the first page data of the second plane is sent to the first data latches DL21 of the second plane (3). While second page data of the second plane is transmitted to the cache latches CL2, the second page data of the first plane is sent to the second data latches DL12 of the first plane (4). While third page data of the first plane is transmitted to the cache latches CL1, the second page data of the second plane is sent to the second data latches DL22 of the second plane (5). While third page data of the second plane is transmitted to the cache latches CL2, the third page data of the first plane is sent to the third data latches DL13 of the first plane (6). The third page data of the second plane is transferred to the third data latches DL23 of the second plane (7).

Afterwards, the first through third page data of each plane may be simultaneously programmed at a selected physical page of each plane through one-shot programming That is, the first through third page data of the first plane may be simultaneously programmed at a selected physical page of the first plane, and the first through third page data of the second plane may be simultaneously programmed at a selected physical page of the second plane (8).

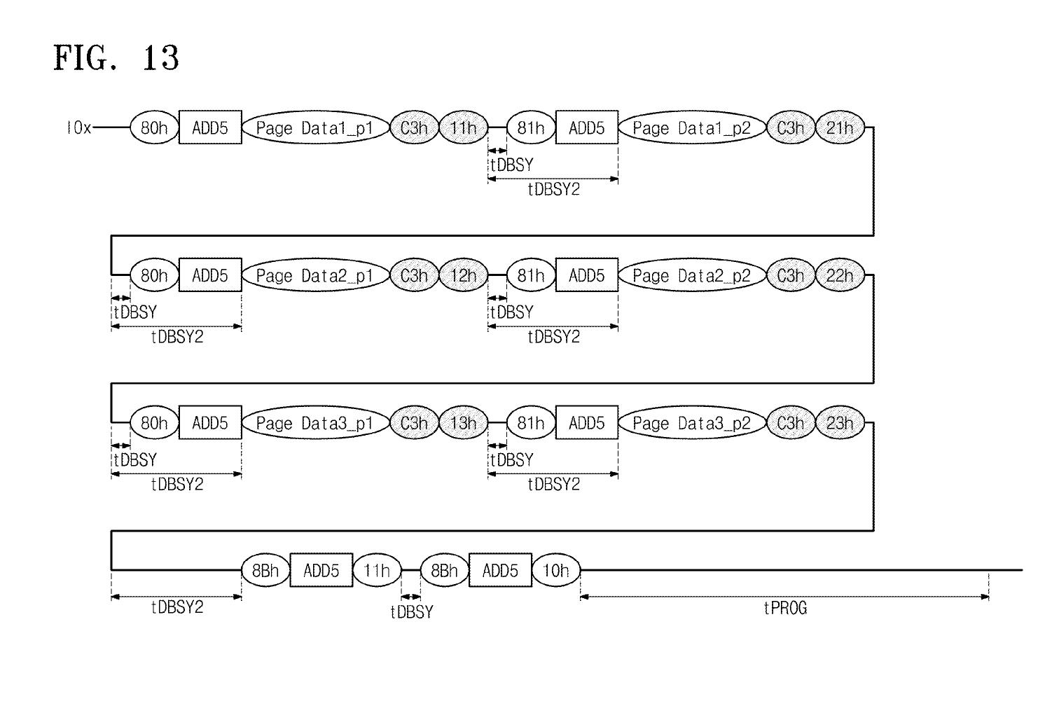

FIG. 13 is a diagram showing a multi-plane program sequence produced to execute a program operation method shown in FIG. 12, according to an embodiment of the inventive concept. Referring to FIG. 13, a memory controller 200 (refer to FIG. 1) produces a multi-plane program sequence in response to a program operation request of a host. A nonvolatile memory device 100 performs a program operation in compliance with the multi-plane program sequence. In FIG. 13, while the program operation is conducted in compliance with the multi-plane program sequence of the inventive concept, a dummy busy time tDBSY2 for data set-up may be observed by an external device only at one time. Thus, a time taken to perform a program operation in compliance with the multi-plane program sequence shown in FIG. 13 is shorter than that taken to perform a program operation in compliance with the multi-plane program sequence shown in FIG. 9. The multi-plane program sequence may be formed of four program sequences as follows.

In a first program sequence, after a program sequence start command 80h and an address ADDS are received, first page data Page Data1_p1 of a first plane is transmitted to cache latches CL1 of the first plane. After a multi-plane dumping command C3h and a latch direction command 11h are received and a dummy busy time tDBSY for two-plane programming elapses, a program sequence start command 81h and an address ADDS are received. After the program sequence start command 81h and the address ADDS are received, first page data Page Data1_p2 of a second plane is transmitted to cache latches CL2 of the second plane. At this time, a dumping operation of the first page data Page Data1_p1 of the first plane is simultaneously conducted. That is, while the first page data Page Data1_p2 of the second plane is sent to the cache latches CL2 of the second plane, the first page data Page Data1_p1 of the first plane is provided to the first data latches DL11 of the first plane. After the first page data Page Data1_p2 of the second plane is transferred to the cache latches of the second plane, a multi-plane dumping command C3h and a latch direction command 21h are received.

The dumping operation on the first page data Page Data1_p1 of the first plane may be conducted during a dummy busy time tDBSY2 for data set-up. However, the dummy busy time tDBSY2 is not observed by the external device.

In a second program sequence, after a program sequence start command 80h and an address ADDS are received, second page data Page Data2_p1 of the first plane is transmitted to the cache latches CL1 of the first plane. At this time, a dumping operation of the first page data Page Data1_p2 of the second plane is simultaneously conducted. That is, while the second page data Page Data2_p1 of the first plane is sent to the cache latches CL1 of the first plane, the first page data Page Data1_p2 of the second plane is provided to the first data latches DL21 of the second plane.

After a multi-plane dumping command C3h and a latch direction command 12h are received and a dummy busy time tDBSY for 2-plane programming elapses, a program sequence start command 81h and an address ADDS are received. After the program sequence start command 81h and the address ADDS are received, second page data Page Data2_p2 of the second plane is transmitted to the cache latches CL2 of the second plane. At this time, a dumping operation of the second page data Page Data2_p1 of the first plane is simultaneously conducted. That is, while the second page data Page Data2_p2 of the second plane is sent to the cache latches CL2 of the second plane, the second page data Page Data2_p1 of the first plane is provided to the second data latches DL12 of the first plane. After the second page data Page Data2_p2 of the second plane is provided to the cache latches CL2 of the second plane, a multi-plane dumping command C3h and a latch direction command 22h are received.

The dumping operation on the first page data Page Data1_p2 of the second plane and the dumping operation on the second page data Page Data2_p1 of the first plane may be conducted during a dummy busy time tDBSY2 for data set-up. However, the dummy busy time tDBSY2 is not observed by the external device.

In a third program sequence, after a program sequence start command 80h and an address ADDS are received, third page data Page Data3_p1 of the first plane is transmitted to the cache latches CL1 of the first plane. At this time, a dumping operation of the second page data Page Data2_p2 of the second plane is simultaneously conducted. That is, while third page data Page Data3_p1 of the first plane is sent to the cache latches CL1 of the first plane, the second page data Page Data2_p2 of the second plane is provided to the second data latches DL22 of the second plane.

After a multi-plane dumping command C3h and a latch direction command 13h are received and a dummy busy time tDBSY for 2-plane programming elapses, a program sequence start command 81h and an address ADDS are received. After the program sequence start command 81h and the address ADDS are received, third page data Page Data3_p2 of the second plane is transmitted to the cache latches CL2 of the second plane. At this time, a dumping operation of the third page data Page Data3_p1 of the first plane is simultaneously conducted. That is, while the third page data Page Data3_p2 of the second plane is sent to the cache latches CL2 of the second plane, the third page data Page Data3_p1 of the first plane is provided to the third data latches DL13 of the first plane. After the third page data Page Data3_p2 of the second plane is provided to the cache latches CL2 of the second plane, a multi-plane dumping command C3h and a latch direction command 23h are received.

The dumping operation on the second page data Page Data2_p2 of the second plane and the dumping operation on the third page data Page Data3_p1 of the first plane may be conducted during a dummy busy time tDBSY2 for data set-up. However, the dummy busy time tDBSY2 is not observed by the external device.

In a third program sequence, after the multi-plane dumping command C3h and the latch direction command 23h are received, a dumping operation on the third page data Page Data3_p2 of the second plane is conducted during a dummy busy time tDBSY2 for data set-up. After the latch direction command 23h is received and the dummy busy time tDBSY2 elapses, a program start command 8Bh, an address ADDS, and a confirm command 11h corresponding to the first plane are received. After a dummy busy time tDBSY for 2-plane programming elapses, a program start command 8Bh, an address ADDS, and a confirm command 11h corresponding to the second plane are received. Afterwards, during a program operation, the first through third page data of each plane may be programmed at a selected physical page of each plane. For example, the first through third page data Page Data1_p1 through Page Data3_p1 of the first plane are simultaneously programmed at a selected physical page through one-shot programming. The first through third page data Page Data1_p2 through Page Data3_p2 of the second plane are simultaneously programmed at a selected physical page through one-shot programming.

The first page data Page Data1_p1, the second page data Page Data2_p1, and the third page data Page Data3_p1 of the first plane are LSB, CSB, or MSB page data, and the first page data Page Data1_p2, the second page data Page Data2_p2, and the third page data Page Data3_p2 of the second plane are LSB, CSB, or MSB page data. For example, first page data Page Data1_p1 and Page Data1_p2 of the first and second planes are LSB page data, second page data Page Data2_p1 and Page Data2_p2 of the first and second planes are CSB page data, and third page data Page Data3_p1 and Page Data3_p2 of the first and second planes are MSB page data.

According to the above-described multi-plane program sequence, the nonvolatile memory device 100 of the inventive concept may continue to receive data from the memory controller 200 regardless of whether a dumping operation is conducted at any one plane, thereby making it possible to shorten a time taken to perform a program operation of a memory system.

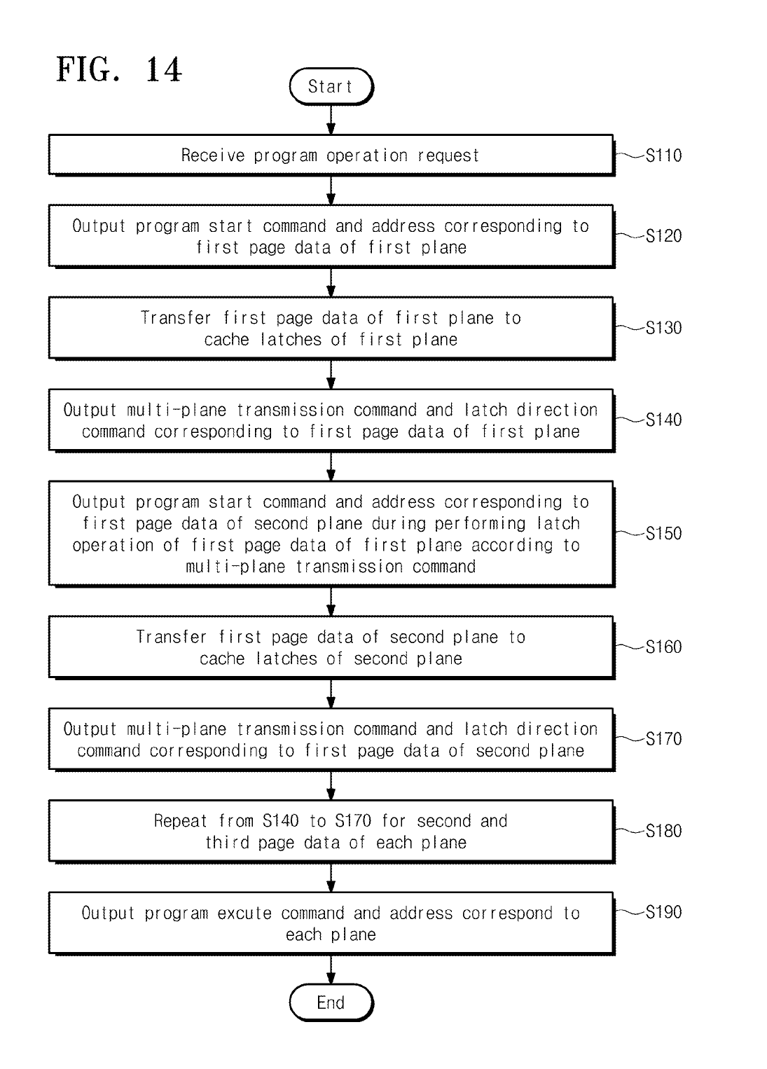

FIG. 14 is a flow chart schematically illustrating an operation of a memory controller in compliance with the multi-plane program sequence shown in FIG. 13. Referring to FIGS. 13 and 14, it is assumed that each memory cell of a nonvolatile memory device 100 (refer to FIG. 1) is a multi-level cell storing 3-bit data. However, the inventive concept is not limited thereto. Steps S120 through S190 show an operation of a memory controller in compliance with a multi-plane program sequence.

In step S110, a memory controller 200 receives a program operation request from a host. The memory controller 200 may output a multi-plane program sequence in response to the program operation request.

In step S120 the memory controller 120 outputs a program sequence start command 80h and an address ADDS corresponding to first page data Page Data1_p1 of a first plane.

In step S130, the memory controller 200 transfers the first page data Page Data1_p1 of the first plane to cache latches CL1 of the first plane, based on the address ADDS corresponding to the first plane.

In step S140, the memory controller 200 outputs a multi-plane dumping command C3h and a latch direction command 11h corresponding to the first page data Page Data1_p1 of the first plane. First data latches DL11 of the first plane may be selected as data latches to which the first page data Page Data1_p1 of the first plane is to be transferred, depending on the latch direction command 11h.

In step S150, while the nonvolatile memory device 100 conducts a dumping operation on the first page data Page Data1_p1 of the first plane in response to the multi-plane dumping command C3h and the latch direction command 11h, the memory controller 200 outputs a program sequence start command 81h and an address ADDS corresponding to first page data Page Data1_p2 of a second plane.

In step S160, the memory controller 200 transfers the first page data Page Data1_p2 of the second plane to cache latches CL2 of the second plane, based on the address ADDS corresponding to the second plane.

In step S170, the memory controller 200 outputs a multi-plane dumping command C3h and a latch direction command 21h corresponding to the first page data Page Data1_p2 of the second plane. First data latches DL21 of the second plane may be selected as data latches to which the first page data Page Data1_p2 of the second plane is to be transferred, depending on the latch direction command 21h.

In step S180, steps S140 through S170 are repeated until second and third page data Page Data2_p1, Page Data2_p2, Page Data3_p1, and Page Data3_p2 of the first and second planes are transferred to data latches DL12, DL13, DL22, and DL23 of the first and second planes. If each memory cell of the nonvolatile memory device 100 stores 2-bit data, steps S140 through S170 are repeated until second page data Page Data2_p1 and Page Data2_p2 of the first and second planes are transferred to data latches DL12 and DL22 of the first and second planes.

In step S190, the memory controller 200 outputs a program execution command 8Bh and an address ADDS corresponding to each plane. For example, the memory controller 200 outputs a program execution command 8Bh, an address ADDS, and a confirm command 11h corresponding to the first plane. The memory controller 200 outputs a program execution command 8Bh, an address ADDS, and a confirm command 10h corresponding to the second plane. After receiving the confirm command 10h, the nonvolatile memory device 100 programs the first through third page data Page Data1_p1, Page Data2_p1, and Page Data3_p1 at the first plane and the first through third page data Page Data1_p2, Page Data2_p2, and Page Data3_p2 at the second plane. For example, the first through third page data Page Data1_p1 through Page Data3_p1 of the first plane are simultaneously programmed at a selected physical page through one-shot programming. The first through third page data Page Data1_p2 through Page Data3_p2 of the second plane are simultaneously programmed at a selected physical page through one-shot programming.

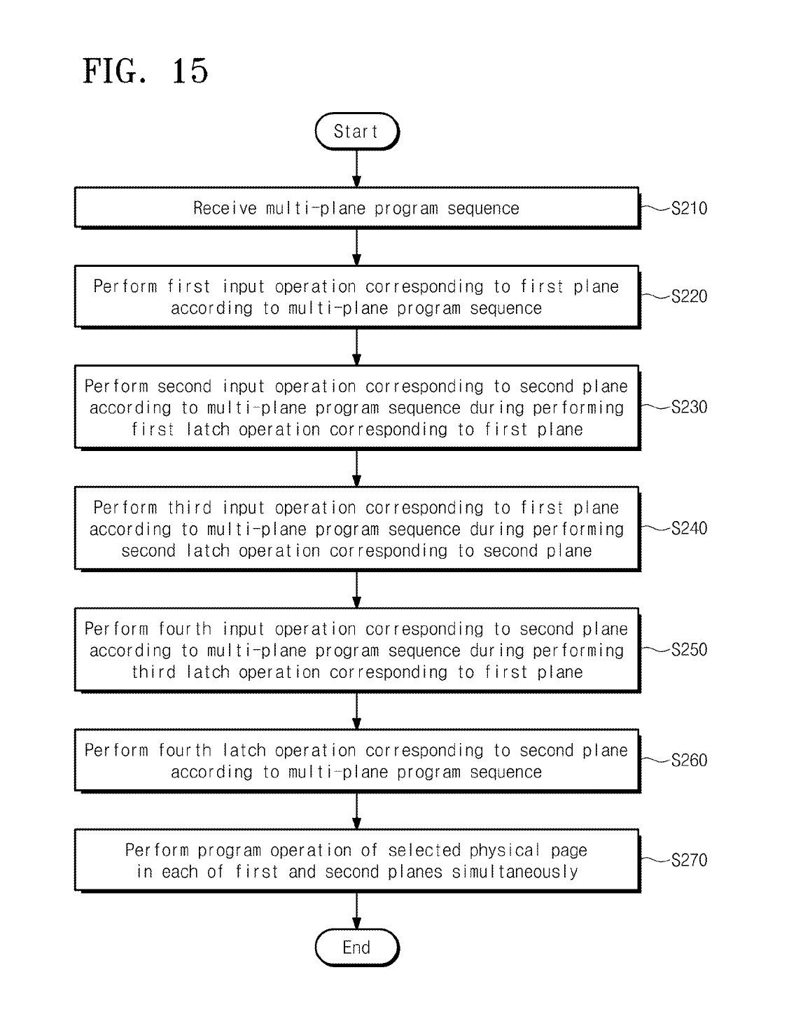

FIG. 15 is a flow chart schematically illustrating an operation of a nonvolatile memory device in compliance with a multi-plane program sequence shown in FIG. 13. Referring to FIGS. 13 and 15, it is assumed that memory cells of a nonvolatile memory device 100 (refer to FIG. 1) are multi-level cells each storing 2-bit data. However, the inventive concept is not limited thereto.

In step S210, the nonvolatile memory device 100 receives a multi-plane program sequence. Steps S220 through S270 show an operation of a nonvolatile memory device in compliance with a multi-plane program sequence.

In step S220, the nonvolatile memory device 100 performs a first input operation corresponding to a first plane. During the first input operation, the nonvolatile memory device 100 receives a program start command 80h and an address ADDS corresponding to the first plane. Also, the nonvolatile memory device 100 receives first page data Page Data1_p1 of the first plane corresponding to the address ADDS. The first page data Page Data1_p1 thus received may be stored in cache latches CL1 of the first plane.

In step S230, while a first dumping operation corresponding to the first plane is conducted, the nonvolatile memory device 100 performs a second input operation corresponding to a second plane. During the second input operation, the nonvolatile memory device 100 receives a program start command 81h and an address ADDS corresponding to the second plane. Also, the nonvolatile memory device 100 receives first page data Page Data1_p2 of the second plane corresponding to the address ADDS. The first page data Page Data1_p2 thus received may be stored in cache latches CL2 of the second plane. The first page data Page Data1_p1 of the first plane is transferred from the cache latches CL1 to first data latches DL11 of the first plane through the first dumping operation.

In step S240, while a second dumping operation corresponding to the second plane is conducted, the nonvolatile memory device 100 performs a third input operation corresponding to a first plane. During the third input operation, the nonvolatile memory device 100 receives a program start command 80h and an address ADDS corresponding to the first plane. Also, the nonvolatile memory device 100 receives second page data Page Data2_p1 of the first plane corresponding to the address ADDS. The second page data Page Data2_p1 thus received may be stored in the cache latches CL1 of the first plane. The first page data Page Data1_p2 of the second plane is transferred from the cache latches CL2 to first data latches DL21 of the second plane through the second dumping operation.

In step S250, while a third dumping operation corresponding to the first plane is conducted, the nonvolatile memory device 100 performs a fourth input operation corresponding to a second plane. During the fourth input operation, the nonvolatile memory device 100 receives a program start command 81h and an address ADDS corresponding to the second plane. Also, the nonvolatile memory device 100 receives second page data Page Data2_p2 of the second plane corresponding to the address ADDS. The second page data Page Data2_p2 thus received may be stored in the cache latches CL2 of the second plane. The second page data Page Data2_p1 of the first plane is transferred from the cache latches CL1 to second data latches DL12 of the first plane through the third dumping operation.

In step S260, the nonvolatile memory device 100 performs a fourth dumping operation corresponding to the second plane. The second page data Page Data2_p2 of the second plane is transferred from the cache latches CL2 to second data latches DL22 of the second plane through the fourth dumping operation.

If each memory cell of the nonvolatile memory device 100 stores 3-bit data, the nonvolatile memory device 100 repeats steps S240 and S250 with respect to third page data Page Data3_p1 and Page Data3_p2 of the first and second planes.

In step S270, the nonvolatile memory device 100 programs selected physical pages of the first and second planes at the same time. For example, the nonvolatile memory device 100 receives a program execution command 8Bh, an address ADDS, and a confirm command 11h corresponding to the first plane. Also, the nonvolatile memory device 100 receives a program execution command 8Bh, an address ADDS, and a confirm command 10h corresponding to the second plane. After receiving the confirm command 10h, the nonvolatile memory device 100 executes programming at the first and second planes. The first and second page data Page Data1_p1 and Page Data2_p1 of the first plane is simultaneously programmed at a selected physical page through one-shot programming. The first and second page data Page Data1_p2 and Page Data2_p2 of the second plane is simultaneously programmed at a selected physical page through one-shot programming.

If each memory cell of the nonvolatile memory device 100 stores 3-bit data, first through third page data Page Data1_p1 through Page Data3_p1 of the first plane are simultaneously programmed at a selected physical page through one-shot programming First through third page data Page Data1_p2 through Page Data3_p2 of the second plane are simultaneously programmed at a selected physical page through one-shot programming.

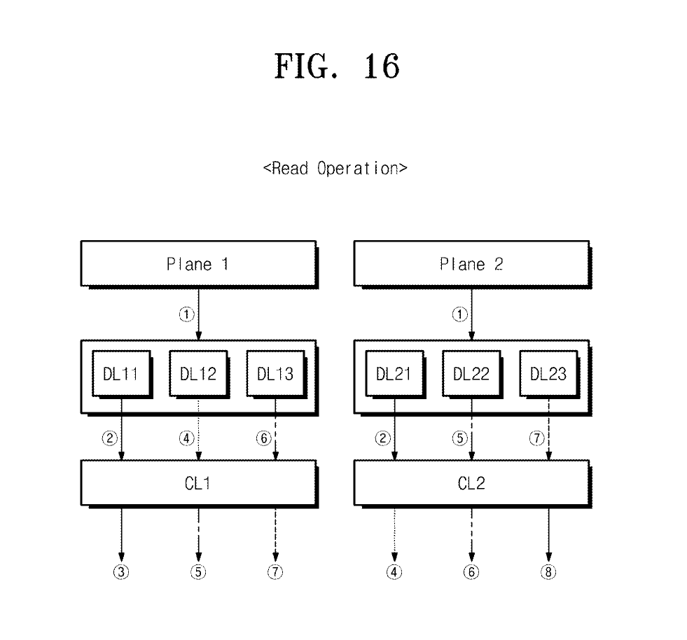

FIG. 16 is a diagram showing a data transfer order of a read operation method according to another embodiment of the inventive concept. Referring to FIG. 16, it is assumed that a page buffer circuit corresponding to each plane contains cache latches for storing a page of data and data latches for storing three pages of data. For example, a page buffer circuit corresponding to a first plane includes cache latches CL1 and data latches DL11, DL12, and DL13, and a page buffer circuit corresponding to a second plane includes cache latches CL2 and data latches DL21, DL22, and DL23. A nonvolatile memory device 100 (refer to FIG. 1) may perform the following operations (1) through (8) in compliance with a multi-plane read sequence that a memory controller 200 (refer to FIG. 1) generates.

A plurality of page data stored at a selected physical page of each plane may be simultaneously sensed through one sensing operation corresponding to one-shot programming. The plurality of page data thus sensed is stored in data latches of each plane (1). For example, first page data of the first plane is stored in the first data latches DL11 of the first plane, second page data of the first plane in the second data latches DL12 of the first plane, and third page data of the first plane in the third data latches DL13 of the first plane. First page data of the second plane is stored in the first data latches DL21 of the second plane, second page data of the second plane in the second data latches DL22 of the second plane, and third page data of the second plane in the third data latches DL23 of the second plane.

The first page data of the first and second planes is transferred to the cache latches CL1 and CL2 of the first and second planes just after an operation corresponding to (2) is conducted. Afterwards, the first page data of the first plane is first of all output (3).

The first page data of the second plane is output while the second page data of the first plane is transferred to the cache latches CL1 (4). The second page data of the first plane is output while the second page data of the second plane is transferred to the cache latches CL2 (5). The second page data of the second plane is output while the third page data of the first plane is transferred to the cache latches CL1 (6). The third page data of the first plane is output while the third page data of the second plane is transferred to the cache latches CL2 (7). Finally, the third page data of the second plane is output (8).

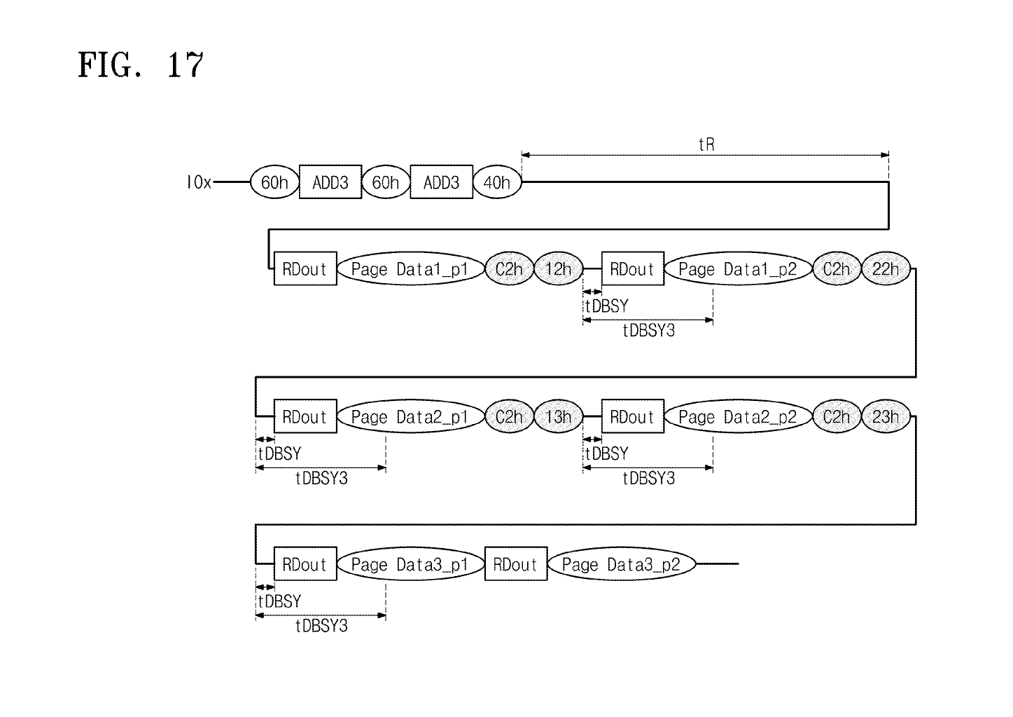

FIG. 17 is a diagram showing a multi-plane read sequence produced to execute the read operation method shown in FIG. 16, according to an embodiment of the inventive concept.

Referring to FIGS. 16 and 17, a memory controller 200 (refer to FIG. 1) produces a multi-plane read sequence in response to a read operation request of a host. A nonvolatile memory device 100 performs a read operation in compliance with the multi-plane read sequence. In FIG. 17, while the read operation is conducted in compliance with the multi-plane read sequence of the inventive concept, a dummy busy time tDBSY3 for data set-up may not be observed by an external device. Thus, a time taken to perform a read operation in compliance with the multi-plane read sequence shown in FIG. 17 is shorter than that taken to perform a read operation in compliance with the multi-plane read sequence shown in FIG. 10. The multi-plane read sequence may be formed of four read sequences as follows.

In a first read sequence, a read start command 60h and an address ADD3 corresponding to a first plane are received, and then a read start command 60h and an address ADD3 corresponding to a second plane are received. After a data sensing command 40h is received, pages data Page Data1_p1, Page Data2_p1, Page Data3_p1, Page Data1_p2, Page Data2_p2, and Page Data3_p2 are simultaneously sensed from selected pages of the first and second planes. The sensed pages data Page Data1_p1, Page Data2_p1, Page Data3_p1, Page Data1_p2, Page Data2_p2, and Page Data3_p2 are stored in data latches of the first and second planes.

The first through third page data Page Data1_p1 through Page Data3_p1 are sensed from the first plane, and the sensed first through third page data Page Data1_p1 through Page Data3_p1 are stored at first through third data latches DL11 through DL13 of the first plane. For example, the first page data Page Data1_p1 is stored in the first data latches DL11, the second page data Page Data2_p1 in the second data latches DL12, and the third page data Page Data3_p1 in the third data latches DL13.

During a read time tR, the first through third page data Page Data1_p1 through Page Data3_p1 are sensed from the first plane, and the sensed first through third page data Page Data1_p1 through Page Data3_p1 are stored at the first through third data latches of the first plane. During the read time tR, also, the first page data Page Data1_p1 is transmitted from the first data latches DL11 to cache latches CL1.

During the read time tR, the first through third page data Page Data1_p2 through Page Data3_p2 are sensed from the second plane, and the sensed first through third page data Page Data1_p2 through Page Data3_p2 are stored at first through third data latches DL21 through DL23 of the second plane. For example, the first page data Page Data1_p2 is stored in the first data latches DL21, the second page data Page Data2_p2 in the second data latches DL22, and the third page data Page Data3_p2 in the third data latches DL23. During the read time tR, the first page data Page Data1_p2 is transmitted from the first data latches DL21 to cache latches CL2.

Thus, during the read time tR, the first through third page data Page Data1_p1 through Page Data3_p1 and the first through third page data Page Data1_p2 through Page Data3_p2 are simultaneously sensed from selected physical pages of the first and second planes by a read method corresponding to one-shot programming.

In a second read sequence, the first page data Page Data1_p1 of the first plane is output in response to an input of a data output command RDout corresponding to the first plane.

After the first page data Page Data1_p1 of the first plane is output, a multi-plane dumping command C2h and a latch direction command 12h are received. Received is a data output command RDout corresponding to the second plane after the latch direction command 12h is received and a dummy busy time tDBSY for 2-plane reading elapses. After the data output command RDout corresponding to the second plane is received, first page data Page Data1_p2 of the second plane is output. At this time, a dumping operation on second page data Page Data2_p1 of the first plane is simultaneously performed in compliance with the multi-plane dumping command C2h. That is, while the first page data Page Data1_p2 of the second plane is output, the second page data Page Data2_p1 of the first plane is transferred from the second data latches DL12 to the cache latches CL1. Received are both a multi-plane dumping command C2h and a latch direction command 22h after an output of the first page data Page Data1_p2 of the second plane is completed.

The dumping operation on the second page data Page Data2_p1 of the first plane is conducted during a dummy busy time tDBSY3 for data-out. However, the dummy busy time tDBSY3 for data-out may not be observed by an external device.

In a third read sequence, a data output command RDout corresponding to the first plane is received after the latch direction command 22h is received and the dummy busy time tDBSY for 2-plane reading elapses. After the data output command RDout corresponding to the first plane is received, the second page data Page Data2_p1 of the first plane is output. At this time, a dumping operation on second page data Page Data2_p2 of the second plane is simultaneously performed in compliance with the multi-plane dumping command C2h. That is, while the second page data Page Data2_p1 of the first plane is output, the second page data Page Data2_p2 of the second plane is transferred from the second data latches DL22 to the cache latches CL2. Received are both a multi-plane dumping command C2h and a latch direction command 13h after an output of the second page data Page Data2_p1 of the first plane is completed.

Received is a data output command RDout corresponding to the second plane after the latch direction command 13h is received and a dummy busy time tDBSY for 2-plane reading elapses. After the data output command RDout corresponding to the second plane is received, second page data Page Data2_p2 of the second plane is output. At this time, a dumping operation on third page data Page Data3_p1 of the first plane is simultaneously performed in compliance with the multi-plane dumping command C2h. That is, while the second page data Page Data2_p2 of the second plane is output, the third page data Page Data3_p1 of the first plane is transferred from the third data latches DL13 to the cache latches CL1. Received are both a multi-plane dumping command C2h and a latch direction command 23h after an output of the second page data Page Data2_p2 of the second plane is completed.

The dumping operation on the second page data Page Data2_p2 of the second plane and the dumping operation on the third page data Page Data3_p1 of the first plane are conducted during a dummy busy time tDBSY3 for data-out. However, the dummy busy time tDBSY3 for data-out may not be observed by an external device.

In a fourth sequence, a data output command RDout corresponding to the first plane is received after the latch direction command 23h is received and a dummy busy time tDBSY for 2-plane reading elapses. After the data output command RDout corresponding to the first plane is received, the third page data Page Data3_p1 of the first plane is output. At this time, a dumping operation on third page data Page Data3_p2 of the second plane is simultaneously performed in compliance with the multi-plane dumping command C2h. That is, while the third page data Page Data3_p1 of the first plane is output, the third page data Page Data3_p2 of the second plane is transferred from the third data latches DL23 to the cache latches CL2. Received is a data output command RDout corresponding to the second plane after an output of the third page data Page Data3_p1 of the first plane is completed. The third page data Page Data3_p2 of the second plane is output in response to an input of the data output command RDout corresponding to the second plane.

The dumping operation on the third page data Page Data3_p2 of the second plane is conducted during a dummy busy time tDBSY3 for data-out. However, the dummy busy time tDBSY3 for data-out may not be observed by an external device.

According to the above-described multi-plane read sequence, the nonvolatile memory device 100 of the inventive concept may continue to output data to a memory controller 200 regardless of whether a dumping operation is conducted at any one plane, thereby making it possible to shorten a time taken to perform a read operation of a memory system.

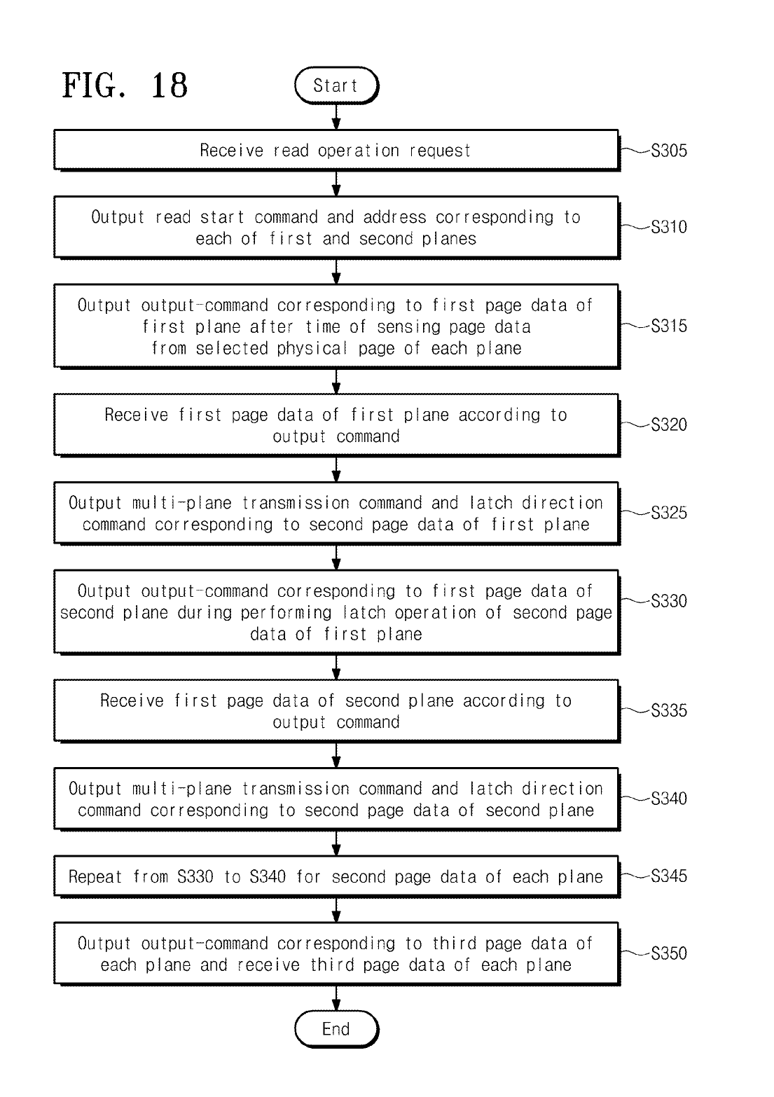

FIG. 18 is a flow chart schematically illustrating an operation of a memory controller in compliance with a multi-plane read sequence shown in FIG. 17. Referring to FIGS. 17 and 18, it is assumed that each memory cell of a nonvolatile memory device 100 (refer to FIG. 1) is a multi-level cell storing 3-bit data. However, the inventive concept is not limited thereto.

In step S305, a memory controller 200 receives a read operation request from a host. The memory controller 200 may output a multi-plane read sequence in response to the program read request. Steps S310 through S350 show an operation of a memory controller in compliance with a multi-plane read sequence.

In step S310, the memory controller 200 outputs a read start command 60h and an address ADD3 corresponding to each plane. For example, the memory controller 200 sequentially outputs a read start command 60h and an address ADD3 corresponding to a first plane and a read start command 60h and an address ADD3 corresponding to a second plane. Afterwards, the memory controller 200 outputs a data sensing command 40h. Sensed is a plurality of page data stored in selected physical pages of first and second planes in compliance with an input of the data sensing command 40h, and the sensed data is stored in data latches of a page buffer circuit. For example, first through third page data Page Data1_p1 through Page Data3_p1 of the first plane may be stored in first through third data latches DL11 through DL13 of a page buffer circuit corresponding to the first plane. First through third page data Page Data1_p2 through Page Data3_p2 of the second plane may be stored in first through third data latches DL21 through DL23 of a page buffer circuit corresponding to the second plane. Also, a dumping operation on the first page data Page Data1_p1 of the first plane is conducted during a read operation tR. A dumping operation on the first page data Page Data1_p2 of the second plane is conducted during the read operation tR.

In step S315, the memory controller 200 outputs a data output command RDout corresponding to the first page data Page Data1_p1 of the first plane after the data sensing command 40h is received and the read time tR when a plurality of page data is sensed from each plane elapses.

In step S320, the memory controller 200 receives the first page data Page Data1_p1 of the first plane that is output in response to the data output command RDout.

In step S325, after receiving the first page data Page Data1_p1 of the first plane, the memory controller 200 outputs a multi-plane dumping command C2h and a latch direction command 12h. A dumping operation on second page data Page Data2_p1 of the first plane is conducted in response to the input of the multi-plane dumping command C2h.

In step S330, the memory controller 200 outputs a data output command RDout corresponding to the second page data Page Data1_p2 of the first plane while the dumping operation on second page data Page Data2_p1 of the first plane is conducted.

In step S335, the memory controller 200 receives the first page data Page Data1_p2 of the second plane that is output in response to the data output command RDout.

In step S340, after receiving the first page data Page Data1_p2 of the second plane, the memory controller 200 outputs a multi-plane dumping command C2h and a latch direction command 22h corresponding to second page data Page Data2_p2 of the second plane. A dumping operation on second page data Page Data2_p2 of the second plane is conducted in response to the input of the multi-plane dumping command C2h.

In step S345, the memory controller repeats steps S330 through S340 with respect to second page data Page Data2_p1 and Page Data2_p2 of the first and second planes. As steps S330 through S340 are repeated, the memory controller 200 sequentially receives second page data Page Data2_p1 and Page Data2_p2 of the first and second planes. Also, a dumping operation on the second page data Page Data2_p2 of the second plane is conducted while the memory controller 200 receives the page data Page Data2_p2 of the second plane.

If memory cells of the nonvolatile memory device 100 are multi-level cells each storing 2-bit data, the multi-plane read sequence is ended after an input of the second page data Page Data2_p2 of the second plane is completed.

In step S350, the memory controller 200 outputs a data output command RDout corresponding to third page data Page Data3_p1 of the first plane. The memory controller 200 receives the third page data Page Data3_p1 of the first plane that is output in response to the data output command RDout. At this time, while the memory controller 200 receives the third page data Page Data3_p1 of the first plane, a dumping operation of third page data Page Data3_p2 of the second plane is conducted in compliance with a multi-plane dumping command C2h and a data direction command 23h. After an input of the third page data Page Data3_p1 of the first plane is completed, the memory controller 200 outputs a data output command RDout corresponding to third page data Page Data3_p2 of the second plane. The memory controller 200 receives the third page data Page Data3_p2 of the second plane that is output in response to the data output command RDout.

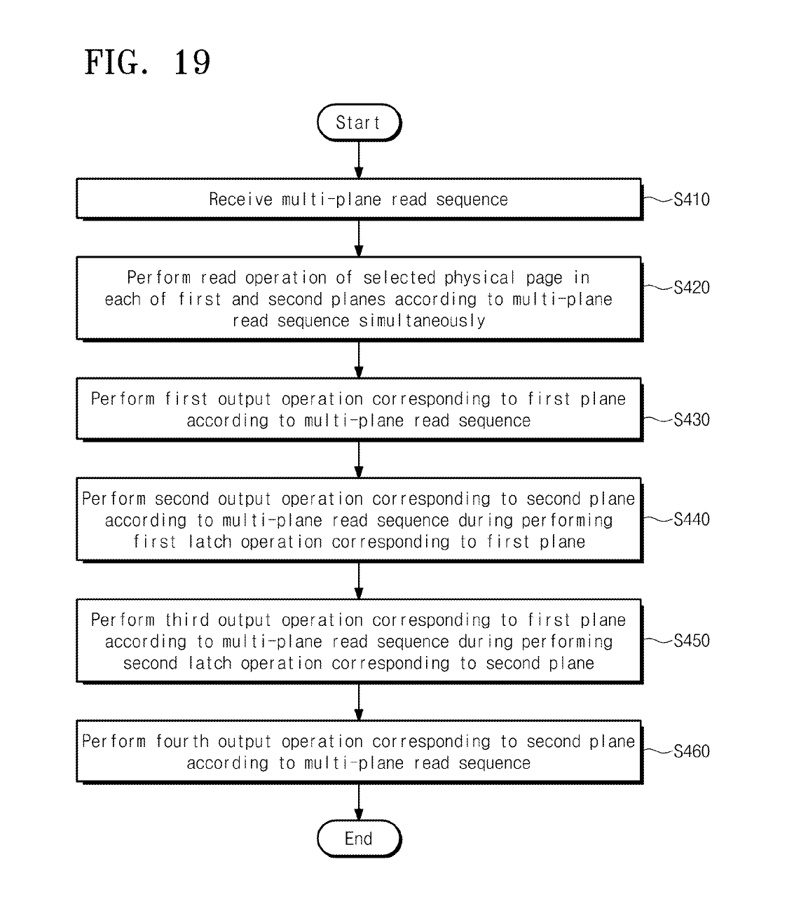

FIG. 19 is a flow chart schematically illustrating an operation of a nonvolatile memory device in compliance with the multi-plane read sequence shown in FIG. 17. Referring to FIGS. 17 and 19, it is assumed that memory cells of a nonvolatile memory device 100 (refer to FIG. 1) are multi-level cells each storing 2-bit data. However, the inventive concept is not limited thereto.

In step S410, the nonvolatile memory device 100 receives a multi-plane read sequence. Steps S420 through S460 show an operation of a nonvolatile memory device in compliance with a multi-plane read sequence.

In step S420, the nonvolatile memory device 100 simultaneously performs read operations on selected physical pages of first and second planes. For example, the nonvolatile memory device 100 receives a read start command 60h and an address ADDS corresponding to each plane. Afterwards, the nonvolatile memory device 100 receives a data sensing command 40h. The nonvolatile memory device 100 simultaneously senses a plurality of page data stored at a selected physical page of each plane in response to the data sensing command 40h. The plurality of page data thus sensed may be stored at data latches of each plane.

Also, the first and second page data Page Data1_p1 and Page Data2_p1 of the first plane are stored in the first and second data latches DL11 and DL12 of the first plane. The first and second page data Page Data1_p2 and Page Data2_p2 of the second plane are stored in the first and second data latches DL21 and DL22 of the second plane. At this time, the first page data Page Data1_p1 and Page Data1_p2 of the first and second planes are transmitted to the cache latches CL1 and CL2 of the first and second planes.

If memory cells of the nonvolatile memory device 100 are multi-level cells each storing 3-bit data, third page data Page Data3_p1 and Page Data3_p2 of the first and second planes are stored in the data latches DL13 and DL23 of the first and second planes.

In step S430, the nonvolatile memory device 100 performs a first output operation corresponding to the first plane. The nonvolatile memory device 100 performs a first output operation corresponding to the first plane in response to a data output command RDout corresponding to the first plane.

In step S440, the nonvolatile memory device 100 performs a second output operation corresponding to the second plane while a first dumping operation corresponding to the first plane is conducted. That is, the nonvolatile memory device 100 outputs the first page data Page Data1_p2 of the second plane while a dumping operation on the second page data Page Data2_p1 of the first plane is carried out.

In step S450, the nonvolatile memory device 100 performs a third output operation corresponding to the first plane while a second dumping operation corresponding to the second plane is conducted. That is, the nonvolatile memory device 100 outputs the second page data Page Data2_p1 of the first plane while a dumping operation on the second page data Page Data2_p2 of the second plane is carried out.

In step S460, the nonvolatile memory device 100 performs a fourth output operation corresponding to the second plane. That is, the nonvolatile memory device 100 outputs the second page data Page Data2_p2 of the second plane.

If memory cells of the nonvolatile memory device 100 are multi-level cells each storing 3-bit data, steps S440 through S460 are repeated with respect to third page data Page Data3_p1 and Page Data3_p2 of the first and second planes, respectively.

The inventive concept is applicable to a solid state drive (SSD).

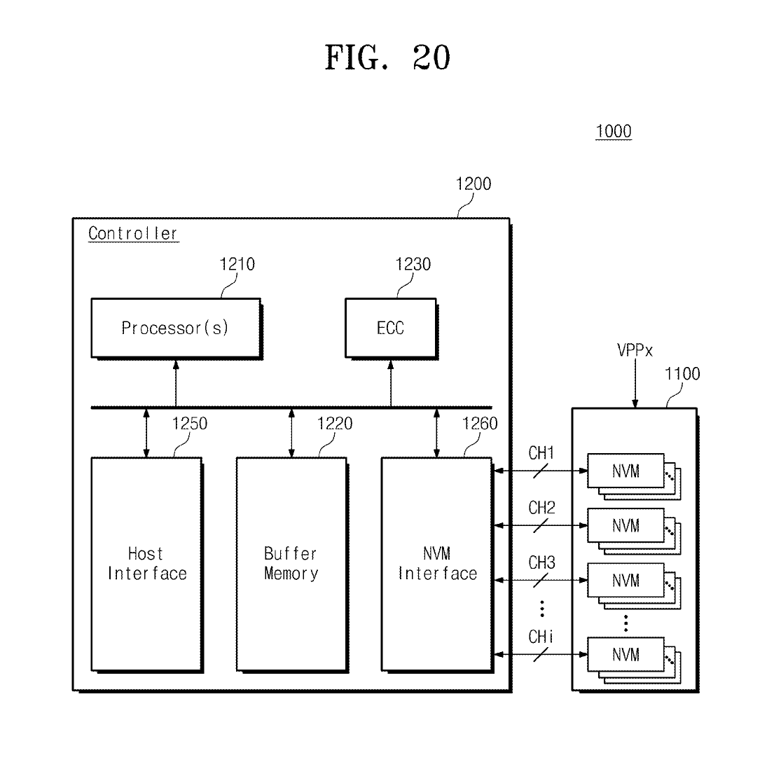

FIG. 20 is a block diagram schematically illustrating a solid state drive according to an embodiment of the inventive concept. Referring to FIG. 20, a solid state drive (hereinafter, referred to as SSD) 1000 includes a plurality of nonvolatile memory devices 1100 and an SSD controller 1200. Each of the nonvolatile memory devices 1100 is implemented with a nonvolatile memory device 100 shown in FIG. 2. The nonvolatile memory devices 1100 shorten times taken to perform program and read operations by use of a multi-plane operation sequence of the inventive concept.

Optionally, the nonvolatile memory devices 1100 may be implemented to be provided with an external high voltage VPPx. The SSD controller 1200 is connected to the nonvolatile memory devices 1100 through a plurality of channels CH1 to CHi (i being an integer of 2 or more). The SSD controller 1200 includes one or more processors 1210, a buffer memory 1220, an ECC block 1230, a host interface 1250, and a nonvolatile memory interface 1260.

The buffer memory 1220 temporarily stores data needed to drive the SSD controller 1200. In exemplary embodiments, the buffer memory 1220 may include a plurality of memory lines each of which stores data or a command. The memory lines may be mapped onto cache lines via various methods.

The ECC block 1230 is configured to calculate an ECC value of data to be programmed at a write operation, correct an error of read data according to an ECC value at a read operation, and correct an error of data restored from the nonvolatile memory device 1100 at a data restoration operation. Although not shown in the figures, a code memory may be further provided to store code data needed to drive the SSD controller 1200. The code memory may be implemented with a nonvolatile memory device.

The host interface 1250 provides an interface with an external device.

The nonvolatile memory interface 1260 interfaces with the nonvolatile memory devices 1100. The multi-plane operation sequence of the inventive concept is transferred to the nonvolatile memory devices 1100 through the nonvolatile memory interface 1260.

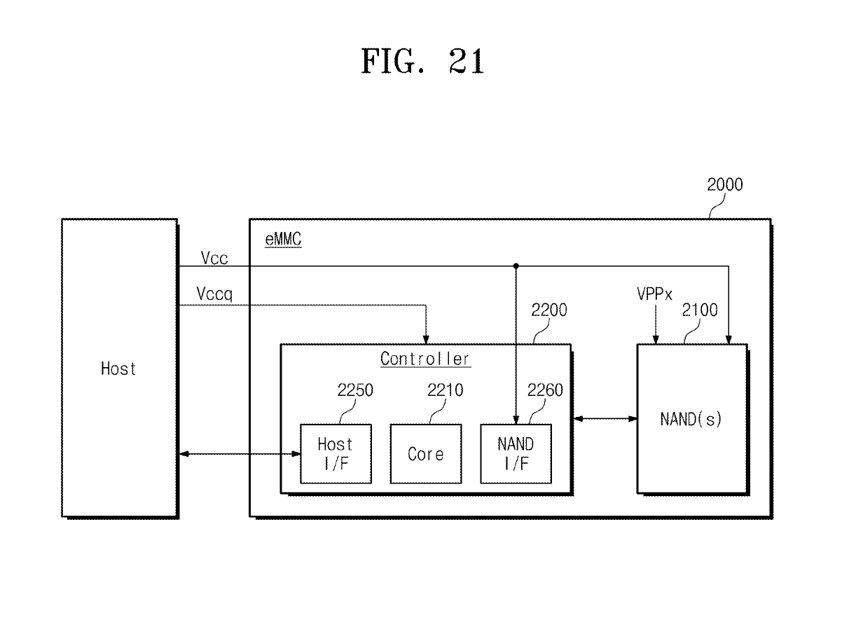

The inventive concept is applicable to an eMMC (e.g., an embedded multimedia card, moviNAND, iNAND, etc.). FIG. 21 is a block diagram schematically illustrating an eMMC according to an embodiment of the inventive concept. Referring to FIG. 21, an eMMC 2000 includes one or more NAND flash memory devices 2100 and a controller 2200.

The NAND flash memory device 2100 may be a single data rate (SDR) or a double data rate (DDR) NAND. Alternatively, the NAND flash memory device 2100 may be a vertical NAND and checks whether or not there is a change in a threshold voltage of a selection line. The NAND flash memory device 2100 may be implemented with a nonvolatile memory device 100 described with reference to FIG. 1. The NAND flash memory device 2100 shortens times taken to perform program and read operations by use of a multi-plane operation sequence of the inventive concept.

The controller 2200 is connected to the NAND flash memory device 2100 via a plurality of channels. The controller 2200 contains one or more controller cores 2210, a host interface 2250, and a NAND interface 2260. The controller core 2210 may control an overall operation of the eMMC 2000.

The host interface 2250 is configured to interface between the controller 2200 and a host.

The NAND interface 2260 is configured to interface between the NAND flash memory device 2100 and the controller 2200. The multi-plane operation sequence of the inventive concept is transferred to the NAND flash memory device 2100 through the NAND interface 2260.

The eMMC 2000 receives power supply voltages Vcc and Vccq from the host. Here, the power supply voltage Vcc (e.g., about 3.3 V) may be supplied to the NAND flash memory device 2100 and the NAND interface 2260, and the power supply voltage Vccq (e.g., about 1.8 V/3.3 V) may be supplied to the controller 2200. In exemplary embodiments, the eMMC 2000 may be optionally supplied with an external high voltage.

The inventive concept is applicable to Universal Flash Storage UFS.

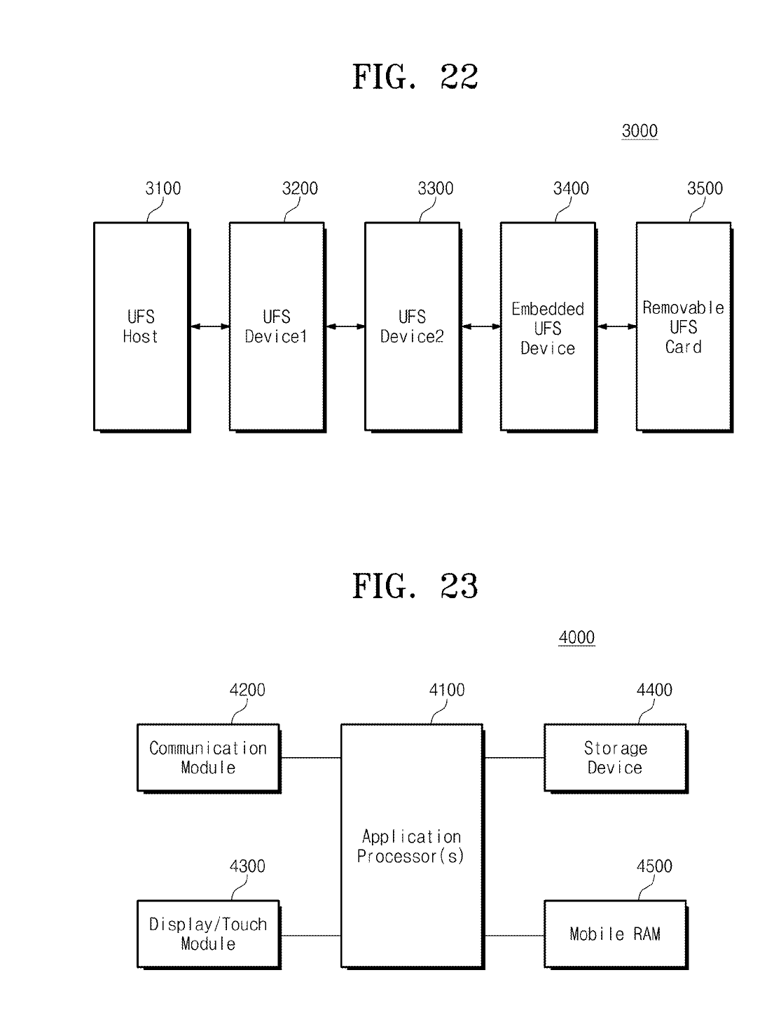

FIG. 22 is a block diagram schematically illustrating a UFS system according to an embodiment of the inventive concept. Referring to FIG. 22, a UFS system 3000 includes a UFS host 3100, UFS devices 3200 and 3300, an embedded UFS device 3400, and a removable UFS card 3500. The UFS host 3100 may be an application processor of a mobile device. Each of the UFS host 3100, the UFS devices 3200 and 3300, the embedded UFS device 3400, and the removable UFS card 3500 may communicate with external devices through the UFS protocol. At least one of the UFS devices 3200 and 3300, the embedded UFS device 3400, and the removable UFS card 3500 may be implemented with a nonvolatile memory device 100 shown in FIGS. 1 and 2. At least one of the UFS devices 3200 and 3300, the embedded UFS device 3400, and the removable UFS card 3500 shortens times taken to perform program and read operations by use of a multi-plane operation sequence of the inventive concept.

Meanwhile, the embedded UFS device 3400 and the removable UFS card 3500 may contain a bridge that communicates using protocols different from the UFS protocol. The UFS host 3100 and the removable UFS card 3500 may communicate through various card protocols (e.g., UFDs, MMC, SD (secure digital), mini SD, Micro SD, and so on).

The inventive concept is applicable to a mobile device.

FIG. 23 is a block diagram schematically illustrating a mobile device 4000 according to an embodiment of the inventive concept. Referring to FIG. 23, a mobile device 4000 includes an application processor 4100, a communication module 4200, a display/touch module 4300, a storage device 4400, and a mobile RAM 4500.

The application processor 4100 controls an overall operation of the mobile device 4000. The communication module 4200 is configured to perform wireless or wire communications with an external device. The display/touch module 4300 is configured to display data processed by the application processor 4100 or to receive data through a touch panel.

The storage device 4400 is configured to store user data. The storage device 4400 may be, but not limited to, a memory card, an eMMC, an SSD, or a UFS device. The storage device 4400 is implemented with a nonvolatile memory device 100 shown in FIGS. 1 and 2. The storage device 4400 shortens times taken to perform program and read operations by use of a multi-plane operation sequence of the inventive concept.

The mobile RAM 4500 is configured to temporarily store data necessary when the mobile device 4000 operates.

A memory system or a storage device according to the inventive concept may be packaged according to any of a variety of different packaging technologies. Examples of such packaging technologies may include the following: PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), and Wafer-Level Processed Stack Package (WSP).

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

1. An operating method of a nonvolatile memory device including at least first and second planes, the method comprising:
receiving a command and an address for a program operation of the first plane, and first data to be programmed at the first plane;
receiving a multi-plane dumping command after the first data is received; and
receiving a command and an address for a program operation of the second plane, and second data to be programmed at the second plane while a multi-plane dumping operation of the first data is conducted on the first plane.

2. The operating method of claim 1, wherein a selected physical page of each of the first and second planes is programmed by a one-shot program process.

3. The operating method of claim 1, wherein the multi-plane dumping operation is conducted between cache latches and data latches of a page buffer circuit corresponding to the first plane.

4. The operating method of claim 1, wherein the first and second planes share a global buffer included in an input/output circuit.

5. An operating method of a nonvolatile memory device which includes a first plane and a second plane, the operating method comprising:
receiving a first program start command and a first address;
receiving first page data to be programmed at the first plane based upon the first address;
receiving a first multi-plane dumping command after an input of the first page data is completed;
receiving a second program start command and a second address while a dumping operation on the first page data is performed based upon the first multi-plane dumping command; and
receiving second page data to be programmed at the second plane based upon the second address.

6. The operating method of claim 5, further comprising:
receiving a second multi-plane dumping command after an input of the second page data is completed;
receiving a third program start command and a third address while a dumping operation on the second page data is performed based upon the second multi-plane dumping command;
receiving third page data to be programmed at the first plane based upon the third address;
receiving a third multi-plane dumping command after an input of the third page data is completed;
receiving a fourth program start command and a fourth address while a dumping operation on the third page data is performed based upon the third multi-plane dumping command;
receiving fourth page data to be programmed at the second plane based upon the fourth address; and
receiving a fourth multi-plane dumping command after an input of the fourth page data is completed.

7. The operating method of claim 6, further comprising:
conducting a dumping operation on the fourth page data based upon the fourth multi-plane dumping command;
receiving a first program execution command and a fifth address corresponding to the first plane after the dumping operation on the fourth page data is completed; and
receiving a second program execution command and a sixth address corresponding to the second plane.

8. The operating method of claim 6, further comprising:
receiving a fifth program start command and a fifth address while the dumping operation on the fourth page data is performed based upon the fourth multi-plane dumping command;
receiving fifth page data to be programmed at the first plane based upon the fifth address;
receiving a fifth multi-plane dumping command after an input of the fifth page data is completed;
receiving a sixth program start command and a sixth address while a dumping operation on the fifth page data is performed based upon the fifth multi-plane dumping command;
receiving sixth page data to be programmed at the second plane based upon the sixth address; and
receiving a sixth multi-plane dumping command after an input of the sixth page data is completed.

9. The operating method of claim 8, further comprising:
receiving a first program execution command and a seventh address corresponding to the first plane after a dumping operation on the sixth page data is performed based upon the sixth multi-plane dumping command; and
receiving a second program execution command and an eighth address corresponding to the second plane.

10. The operating method of claim 9, wherein the dumping operations on the first, third, and fifth page data are conducted between cache latches and data latches of a page buffer circuit corresponding to the first plane, and wherein the dumping operations on the second, fourth, and sixth page data are conducted between cache latches and data latches of a page buffer circuit corresponding to the second plane.

11. An operating method of a nonvolatile memory device which includes a first plane and a second plane, the operating method comprising:
receiving a read start command, an address, and a data sensing command corresponding to each of the first and second planes;
outputting first page data sensed from the first plane in response to a first data output command after sensing operations on the first and second planes are performed based upon the data sensing commands;
receiving a first multi-plane dumping command after an output of the first page data; and
outputting second page data sensed from the second plane in response to a second data output command while a dumping operation on third page data sensed from the first plane is performed based upon the first multi-plane dumping command.

12. The operating method of claim 11, wherein receiving the read start command, the address, and the data sensing command corresponding to each of the first and second planes comprises:
receiving a first read start command and a first address corresponding to the first plane;
receiving a second read start command and a second address corresponding to the second plane; and
receiving the data sensing commands corresponding to the first and second addresses.

13. The operating method of claim 12, further comprising:
receiving a second multi-plane dumping command after an output of the second page data is completed;
outputting the third page data in response to a third data output command while a dumping operation on fourth page data sensed from the second plane is performed based upon the second multi-plane dumping command; and
outputting the fourth page data in response to a fourth data output command after an output of the third page data is completed.

14. The operating method of claim 13, wherein outputting the fourth page data in response to the fourth data output command after the output of the third page data is completed comprises:
receiving a third multi-plane dumping command after an output of the third page data is completed;
outputting the fourth page data in response to the fourth data output command while a dumping operation on fifth page data sensed from the first plane is performed based upon the third multi-plane dumping command;
receiving a fourth multi-plane dumping command after an output of the fourth page data is completed;
outputting the fifth page data in response to a fifth data output command while a dumping operation on sixth page data sensed from the second plane is performed based upon the fourth multi-plane dumping command; and
outputting the sixth page data in response to a sixth data output command after an output of the fifth page data is completed.

15. The operating method of claim 14, wherein each of first through fourth latch direction commands is received after each of the first through fourth multi-plane dumping commands.

16. The operating method of claim 14, wherein the dumping operations on the third and fifth page data are conducted between cache latches and data latches of a page buffer circuit corresponding to the first plane.

17. The operating method of claim 14, wherein the dumping operations on the fourth and sixth page data are conducted between cache latches and data latches of a page buffer circuit corresponding to the second plane.

18. The operating method of claim 12, wherein receiving the data sensing commands corresponding to the first and second addresses includes the first page data being dumped from data latches of a page buffer circuit corresponding to the first plane to cache latches thereof just after a sensing operation on the first plane is completed.

19. The operating method of claim 12, wherein receiving the data sensing commands corresponding to the first and second addresses includes the second page data being dumped from data latches of a page buffer circuit corresponding to the second plane to cache latches thereof just after a sensing operation on the second plane is completed.

20. The operating method of claim 12, wherein the first and second planes share a global buffer included in an input/output circuit.

21-39. (canceled)
